(19) United States
(12) Patent Application Publication
(10) Pub. No.: US 2025/0311600 A1
(43) Pub. Date: Oct. 2, 2025

(54) LIGHT EMITTING APPARATUS, DISPLAY APPARATUS, IMAGE CAPTURING APPARATUS, AND ELECTRONIC DEVICE

(71) Applicant: CANON KABUSHIKI KAISHA, Tokyo (JP)

(72) Inventors: RYO SATO, Kanagawa (JP); TETSUO TAKAHASHI, Kanagawa (JP); SHOMA HINATA, Kanagawa (JP); YUHI UEDA, Kanagawa (JP); HIROAKI SANO, Tokyo (JP); EISUKE GOMMORI, Kanagawa (JP)

(21) Appl. No.: 19/090,032

(22) Filed: Mar. 25, 2025

(30) Foreign Application Priority Data
Mar. 27, 2024 (JP) 2024-052335

(51) Int. Cl. H10K 59/80

(52) U.S. Cl. CPC H10K 59/879

(57) ABSTRACT

A light emitting apparatus includes a first light emitting element and a second light emitting element disposed on a substrate, and a first lens and a second lens respectively disposed in correspondence with the first light emitting element and the second light emitting element. The first light emitting element has a first light emitting layer containing a chemical compound capable of emitting a light having a wavelength in an infrared range, and the second light emitting element has a second light emitting layer containing a chemical compound capable of emitting a light having a wavelength in a visible light range. The first light emitting element and the second light emitting element are configured to satisfy a specific relationship.

### BACKGROUND OF THE INVENTION

### Technical Field

The present disclosure relates to a light emitting apparatus, more specifically, a light emitting apparatus having an infrared emission function for light-of-sight detection, and a display apparatus, an image capturing apparatus, and an electronic device that include the light emitting apparatus.

### Description of the Related Art

An organic light emitting element (which is also referred to as an organic electroluminescence element (organic EL element)) is an electronic element including a pair of electrodes (an anode and a cathode) and an organic compound layer disposed therebetween. By injecting electrons and holes from the pair of electrodes, excitons of a luminescent organic compound in the organic compound layer are generated, and the organic light emitting element emits light at the time when the excitons return to a ground state.

The recent progress in organic light emitting elements is remarkable, and low drive voltage, various emission wavelengths, high-speed response, and thickness and weight reduction of light emitting devices are proceeding. For this reason, organic light emitting elements are receiving attention as image display apparatuses, such as a viewfinder of a camera, a head mounted display, and a wearable device called smartglasses.

In such a display apparatus, it is desired to detect a visually recognizing point of a user by detecting the line of sight of the user to the display apparatus and reflect the detected line-of-sight information in driving of the display apparatus.

Japanese Patent Laid-Open No. 2021-015731 (hereinafter, PTL 1) describes an apparatus that detects a line of sight by applying infrared light as detection light to an eye of a user looking into a viewfinder and capturing reflected light from the eye with a detector.

In the display apparatus described in PTL 1, a display unit, an infrared emitting unit for line-of-sight detection, and an infrared image capturing unit are mounted on the same board.

When an organic light emitting apparatus is used together with an optical system (eyepiece optical system), visible light is emitted from the display unit of the organic light emitting apparatus and infrared light is emitted from the infrared emitting unit, and visible light and infrared light pass through the same optical lens (eyepiece optical system) and reach the eye of the user.

However, there is the following disadvantage. If infrared light applied from the infrared emitting unit toward the eye is attempted to be delivered to the eye of the user through the same optical lens as the display unit, the amount of light that reaches the eye reduces due to reflection and absorption with the optical lens because of the low directivity of light from the infrared emitting unit, so it is difficult to detect the visually recognizing point of the user.

In the display apparatus described in PTL 1 as well, when the display apparatus is used together with an eyepiece optical system, it is desired to further easily detect the visually recognizing point of the user without reducing the amount of light reaching the eye.

### SUMMARY

The present disclosure is contemplated in view of the above disadvantage, and provides a technology to improve the directivity of infrared light that is emitted from an infrared light emitting element without reducing the viewing angle performance of visible light emitted from a display element (display light emitting element) to thereby make it further easy to detect the visually recognizing point of a user (viewer).

An aspect of the present disclosure provides a light emitting apparatus. The light emitting apparatus includes: a first light emitting element and a second light emitting element disposed on a substrate; and a first lens and a second lens respectively disposed in correspondence with the first light emitting element and the second light emitting element. The first light emitting element has a first light emitting layer containing a chemical compound capable of emitting a light having a wavelength in an infrared range, and the second light emitting element has a second light emitting layer containing a chemical compound capable of emitting a light having a wavelength in a visible light range.

Where an area of a region that light incident through the first lens in a normal direction of the substrate is input to a light emitting region of the first light emitting element or a surrounding part around the light emitting region is denoted by S₁, an area of the light emitting region of the first light emitting element is denoted by S₁′, an area of a region that light incident through the second lens in the normal direction of the substrate is input to a light emitting region of the second light emitting element or a surrounding part around the light emitting region is denoted by S₂, and an area of the light emitting region of the second light emitting element is denoted by S₂′, a relationship that a ratio S₁/S₁′ of the S₁ to the S₁′ is closer to one than a ratio S₂/S₂′ of the S₂ to the S₂′ is satisfied.

Further features of the present disclosure will become apparent from the following description of exemplary embodiments with reference to the attached drawings.

### BRIEF DESCRIPTION OF THE DRAWINGS

FIG. 1 is a diagram that illustrates line-of-sight detection with a light emitting apparatus according to an embodiment of the present disclosure.

FIG. 2 is a schematic plan view that shows an example of a light emitting apparatus according to an embodiment of the present disclosure.

FIG. 3 is a schematic sectional view of the light emitting apparatus, taken along the line III-III in FIG. 2.

FIG. 4 is a schematic diagram that shows the light emitting apparatus shown in FIG. 2.

FIG. 5A is a schematic diagram of an example of a light emitting element in the light emitting apparatus according to the embodiment of the present disclosure in an incident state of virtual light in a normal direction and in a light emitting state from a light emitting region, and FIG. 5B is a schematic diagram of an example of a light emitting element in the light emitting apparatus according to the embodiment of the present disclosure in an incident state of virtual light in a direction inclined by a selected angle θ with respect to the normal direction and in a light emitting state from a light emitting region.

FIG. 6A is a schematic diagram of an example of the light emitting element in the light emitting apparatus according to the embodiment of the present disclosure in an incident state of light in a normal direction, and FIG. 6B is a schematic diagram of an example of the light emitting element in the light emitting apparatus according to the embodiment of the present disclosure in an incident state of light in a diagonal direction.

FIG. 7A is a schematic diagram of an example of the light emitting element in the light emitting apparatus according to the embodiment of the present disclosure in an incident state of light in a normal direction, and FIG. 7B is a schematic diagram of an example of the light emitting element in the light emitting apparatus according to the embodiment of the present disclosure in an incident state of light in a diagonal direction.

FIG. 8A is a schematic diagram of an example of the light emitting element in the light emitting apparatus according to the embodiment of the present disclosure in an incident state of light in a normal direction, and FIG. 8B is a schematic diagram of an example of the light emitting element in the light emitting apparatus according to the embodiment of the present disclosure in an incident state of light in a diagonal direction.

FIGS. 9A and 9B are schematic diagrams of an example of the light emitting element in the light emitting apparatus according to the embodiment of the present disclosure.

FIG. 10 is a schematic sectional view that shows an example of a light emitting apparatus according to an embodiment of the present disclosure.

FIG. 11A is a schematic diagrams of an example of a first light emitting element in the light emitting apparatus according to the embodiment of the present disclosure, and FIG. 11B is a schematic diagrams of an example of a second light emitting element in the light emitting apparatus according to the embodiment of the present disclosure.

FIG. 12 is a diagram that illustrates an example of a light emitting apparatus according to an embodiment of the present disclosure.

FIG. 13 is a schematic exploded view that shows an example of a display apparatus according to an embodiment of the present disclosure.

FIG. 14A is a schematic view that shows an example of an image capturing apparatus according to the present embodiment. FIG. 14B is a schematic view that shows an example of an electronic device according to the embodiment of the present disclosure.

FIG. 15A is a schematic view that shows an example of a display apparatus according to an embodiment of the present disclosure. FIG. 15B is a schematic view that shows an example of a foldable display apparatus.

FIG. 16A is a schematic view that shows an example of a wearable device according to an embodiment of the present disclosure. FIG. 16B is a schematic view that shows an example of a wearable device according to an embodiment of the present disclosure.

### DESCRIPTION OF THE EMBODIMENTS

Hereinafter, embodiments of the present disclosure will be described with reference to the attached drawings. The invention is not limited to only the embodiments described and may be variously modified. Like reference signs denote portions having the same functions in the drawings described below, and the description thereof may be omitted or simplified.

In the embodiments of the present disclosure, the phrase “greater than or equal to XX and less than or equal to YY” or the phrase “XX to YY” that indicates a numeric range means a numeric range including a lower limit and an upper limit that are end points unless otherwise noted. In a case where a numeric ranges is described in a stepwise manner, a selected combination of an upper limit and a lower limit of each numeric range may be determined.

An embodiment of the present disclosure provides a light emitting apparatus. The light emitting apparatus includes: a first light emitting element and a second light emitting element disposed on a substrate; and a first lens and a second lens respectively disposed in correspondence with the first light emitting element and the second light emitting element. The first light emitting element has a first light emitting layer containing a chemical compound capable of emitting a light having a wavelength in an infrared range, and the second light emitting element has a second light emitting layer containing a chemical compound capable of emitting a light having a wavelength in a visible light range.

Where an area of a region that light incident through the first lens in a normal direction of the substrate is input to a light emitting region of the first light emitting element or a surrounding part around the light emitting region is denoted by S₁, an area of the light emitting region of the first light emitting element is denoted by S₁′, an area of a region that light incident through the second lens in the normal direction of the substrate is input to a light emitting region of the second light emitting element or a surrounding part around the light emitting region is denoted by S₂, and an area of the light emitting region of the second light emitting element is denoted by S₂′, a relationship that a ratio S₁/S₁′ of the S₁ to the S₁′ is closer to one than a ratio S₂/S₂′ of the S₂ to the S₂′ is satisfied.

The light emitting apparatus according to the embodiment of the present disclosure includes a first light emitting element and a second light emitting element. The first light emitting element and the second light emitting element can be disposed on a substrate. At this time, the first light emitting element and the second light emitting element may be directly disposed on the substrate or may be disposed on the substrate via an insulating layer. The first light emitting element and the second light emitting element may be disposed on the same substrate or may be disposed respectively on different substrates. In the following description, the term “light emitting element” can be used as a term including the “first light emitting element” and the “second light emitting element”.

The light emitting apparatus according to the embodiment of the present disclosure further includes a first lens and a second lens respectively disposed in correspondence with the first light emitting element and the second light emitting element. In other words, the first light emitting element includes the first lens disposed in correspondence with the first light emitting element, and the second light emitting element includes the second lens disposed in correspondence with the second light emitting element. Each of the first lens and the second lens just needs to be an optical member and may be specifically a microlens. Each of the first lens and the second lens can be disposed on an emission side of light emitted from a corresponding one of the light emitting elements.

The first light emitting element includes at least a light emitting layer (first light emitting layer) containing a chemical compound (or a substance) capable of emitting a light having a wavelength in an infrared range. The first light emitting element may be made up of a first electrode, a functional layer including the first light emitting layer, and a second electrode laminated on the substrate in this order from the substrate side. The first electrode and the second electrode are also referred to as a lower electrode and an upper electrode based on their arrangement position. One of the first electrode and the second electrode is configured as an anode, and the other one is configured as a cathode. The first light emitting element emits light (infrared light) by injecting electrons and holes from the pair of electrodes. The first light emitting layer may contain an organic compound. The first light emitting element may include a color filter, particularly, a color filter that transmits infrared light.

The second light emitting element includes at least a light emitting layer (second light emitting layer) containing a chemical compound (or a substance) capable of emitting a light having a wavelength in a visible light range. The second light emitting element may be made up of a third electrode, a functional layer including the second light emitting layer, and a fourth electrode laminated on the substrate in this order from the substrate side. The third electrode and the fourth electrode are also referred to as a lower electrode and an upper electrode based on their arrangement position. One of the third electrode and the fourth electrode is configured as an anode, and the other one is configured as a cathode. The second light emitting element emits light (visible light) by injecting electrons and holes from the pair of electrodes. The second light emitting layer may contain an organic compound. The second light emitting element may include a color filter.

In the light emitting apparatus according to the embodiment of the present disclosure, where an area of a region (virtual light incident region) formed such that incident virtual light (virtual incident light) through the first lens in a normal direction of a principal surface (a direction perpendicular to the principal surface) of the substrate reaches a light emitting region of the first light emitting element or the light emitting region and a surrounding part around the light emitting region is denoted by S₁, an area of the light emitting region of the first light emitting element is denoted by S₁′, an area of a region (virtual light incident region) formed such that incident virtual light (virtual incident light) through the second lens in the normal direction of the principal surface (the direction perpendicular to the principal surface) of the substrate reaches a light emitting region of the second light emitting element or the light emitting region and a surrounding part around the light emitting region is denoted by S₂, and an area of the light emitting region of the second light emitting element is denoted by S₂′, a relationship that a ratio S₁/S₁′ of the S₁ to the S₁′ is closer to one than a ratio S₂/S₂′ of the S₂ to the S₂′ can be satisfied. Here, virtual light can be regarded as light from a virtual light source, specifically, light (virtual light) applied from a virtual light source through the lens (first or second lens) toward the light emitting region (or the light emitting region and the surrounding part around the light emitting region) of the light emitting element. When there is a relationship that S₁/S₁′ is closer to one than S₂/S₂′, viewing angle characteristics improve in a display unit including a plurality of the second light emitting elements, and directivity improves in an infrared emitting unit including a plurality of the first light emitting elements. The relationship S₁/S₁′=1 may be satisfied.

An embodiment of the present disclosure can provide a determining method for a light emitting element disposed on a substrate and including at least a lens and a light emitting layer. The determining method includes: a step of inputting light (virtual light) through the lens in a normal direction of the substrate;
a step of measuring an area S of a region that the light input through the lens is input to a light emitting region of the light emitting element or the light emitting region and a surrounding part around the light emitting region;
a step of measuring an area S′ of the light emitting region of the light emitting element; and
a step of determining whether a directivity, light extraction efficiency, and output of the light emitting element are high or low in accordance with the S and the S′, more specifically, when a ratio S/S′ of the S to the S′ is close to one, determining that the directivity, light extraction efficiency, and output of the light emitting element are high.

With the thus configured determining method, when the light emitting element extracts light in the normal direction (from the front side) of the substrate, it is possible to determine whether the light emitting element is capable of efficiently extracting light with a large amount. As a result, it is possible to provide the light emitting element having a high directivity, light extraction efficiency, and output.

Furthermore, it is possible to provide a manufacturing method for a light emitting element, including a step of determining whether the directivity, light extraction efficiency, and output of the light emitting element are high or low, by executing the thus configured determining method.

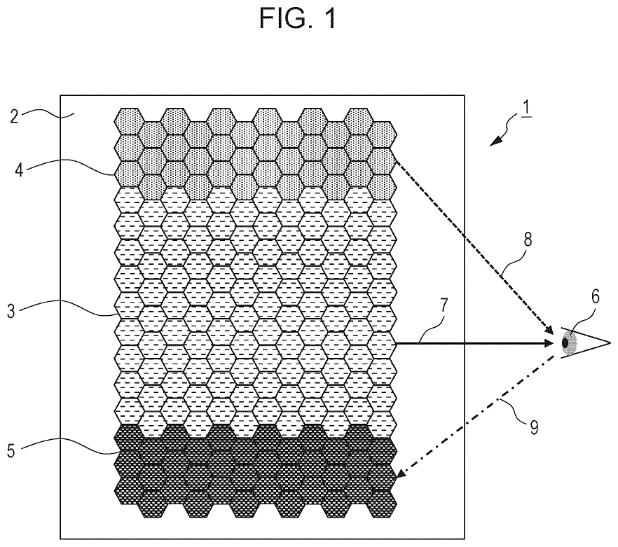

The line-of-sight detection operation of the light emitting apparatus according to the embodiment of the present disclosure will be described with reference to FIG. 1.

FIG. 1 is a schematic diagram that shows an example of the configuration of a light emitting apparatus 1 according to the embodiment of the present disclosure. In FIG. 1, the light emitting apparatus 1 includes a display unit 3 and an infrared emitting unit 4. The display unit 3 and the infrared emitting unit 4 are disposed on a substrate 2. In FIG. 1, a principal surface of the substrate 2, having a light emitting region, in the light emitting apparatus 1 is oriented toward a user (viewer), and the viewer can use the light emitting apparatus 1. In FIG. 1, the continuous line arrow represents light (display light) 7 that exits from the display unit 3 of the light emitting apparatus and enters an eye 6. The dashed line arrow represents light (infrared light) 8 that exits from the infrared emitting unit 4 of the light emitting apparatus 1 and enters the eye 6. The alternate long and short dashed line arrow represents light (infrared reflected light) 9 reflected from the eye 6 of the user. An external system (not shown) can be present outside the light emitting apparatus 1, and the light emitting apparatus 1 is connected to this external system.

The display unit 3 includes a plurality of display light emitting elements, that is, second light emitting elements in the embodiment of the present disclosure. The display unit 3 is capable of forming a display image, such as an image and text, or allowed to be used as a light source for illumination by emitting display light (visible light) 7. A display image may be an image (or picture), such as a still image and a moving image, and may be a monochrome image or a full-color image.

On the other hand, the infrared emitting unit 4 includes a plurality of infrared light emitting elements, that is, the first light emitting elements in the embodiment of the present disclosure, and emits infrared light 8 to the eye 6 of the viewer gazing at a display image.

An image capturing unit 5 includes light receiving elements or image pickup elements. The image capturing unit 5 may be directly disposed on the substrate or may be disposed on the substrate via an insulating layer. The image capturing unit 5 may be formed or disposed on the same substrate with the display unit 3 and the infrared emitting unit 4 or may be formed or disposed on a substrate different from a substrate on which the display unit 3 and the infrared emitting unit 4 are disposed, as a separate member. It is possible to reduce erroneous detection due to incident visible light, so an infrared filter that transmits only infrared light may be provided on the light receiving elements.

The image capturing unit 5 detects reflected light (infrared reflected light) 9 from the eye 6 when the infrared light 8 emitted from the infrared emitting unit 4 reaches the eye 6. Thus, a captured image of the eye 6 is obtained.

The line of sight of the user to the display image is detected from the captured image of the eye 6, obtained through imaging with the infrared light 8. A selected known technique may be applied to line-of-sight detection using the captured image of the eye 6. In an example, a line-of-sight detection method based on a Purkinje image caused by reflection of irradiation light on a cornea may be used.

More specifically, a line-of-sight detection process based on a pupil-cornea reflection method is performed. A line-of-sight vector indicating the orientation (rotational angle) of the eye 6 is calculated in accordance with the pupil image contained in a captured image of the eye 6 and a Purkinje image by using the pupil-cornea reflection method. Thus, the line of sight of a user is detected.

Hereinafter, the present disclosure will be more specifically described by using embodiments. The embodiments are examples of the present disclosure, and the invention is not limited thereto. Requirements described in the embodiments may be used in combination.

### First Embodiment

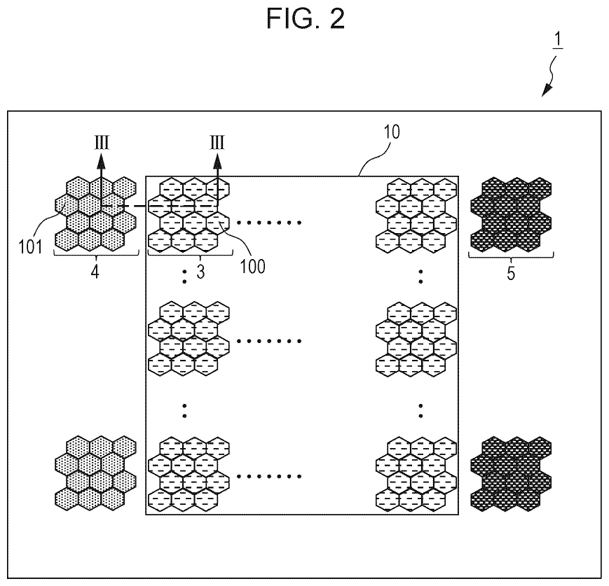

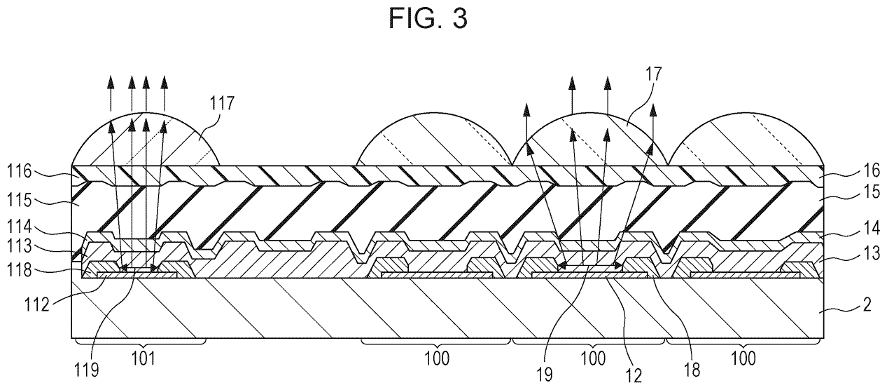

The configuration of a light emitting apparatus according to a first embodiment of the present disclosure will be described. FIG. 2 is a schematic plan view that shows an example of the light emitting apparatus according to the first embodiment of the present disclosure. FIG. 3 is a schematic sectional view of the light emitting apparatus, taken along the line III-III in FIG. 2. Here, a plan view is a view when viewed in a direction perpendicular to the principal surface of a substrate (a normal direction of the principal surface), and a sectional view is a view that shows a cross section perpendicular to the principal surface of the substrate. In the present embodiment, a side on which a functional layer including a light emitting layer is provided with respect to the substrate is referred to as an upper side, and its opposite side is referred to as a lower side. In the embodiment of the present disclosure, a side on which light exits from the light emitting elements is the upper side.

In the present embodiment, the light emitting apparatus 1 includes lenses (microlenses) respectively for the display unit 3 and the infrared emitting unit 4 (more specifically, the light emitting elements disposed in them), so the efficiency of extracting visible light and infrared light is improved.

In FIG. 1, the light emitting apparatus 1 includes the display unit 3 and the infrared emitting unit 4. Specifically, the display unit 3 and the infrared emitting unit 4 are disposed on the substrate 2.

The display unit 3 includes a plurality of display light emitting elements 100, that is, the second light emitting elements in the embodiment of the present disclosure. The plurality of display light emitting elements 100 is arranged on the substrate 2 in a two-dimensional array to form a display region 10. In FIG. 2, an array of the display light emitting elements 100 in a plane is a delta array. The array of the display light emitting elements 100 in a plane may be a stripe array, a square array, a pentile array, or a Bayer array.

The display light emitting element 100 is capable of emitting visible light (display light), that is, producing light and is called a pixel or a sub-pixel. In the present disclosure, a region in which the display unit 3 is disposed can be called a second light emitting region. The color of light emitted from the display light emitting element 100 is not limited, and the display light emitting element 100 may be configured to emit yellow light, white light, or the like, other than red light, green light, or blue light. The plurality of display light emitting elements may be configured to emit different colors. With such a configuration, an image or the like can be formed.

The infrared emitting unit 4 can exercise an infrared emission function for line-of-sight detection and includes a plurality of infrared light emitting elements 101, that is, first light emitting elements in the embodiment of the present disclosure. In FIG. 2, the infrared light emitting elements 101 are arranged on the substrate 2 in a two-dimensional array. In FIG. 2, an array of the infrared light emitting elements 101 in a plane is a delta array. The array of the infrared light emitting elements 101 in a plane may be any one of a stripe array, a square array, a pentile array, and a Bayer array. The infrared emitting unit 4 just needs to include the infrared light emitting elements 101 capable of emitting infrared light, and the configuration of the infrared emitting unit 4 is not limited. The infrared emitting unit 4 may include, for example, organic light emitting elements, LED elements, or the like. In the present disclosure, a region in which the infrared emitting unit 4 is disposed can be called a first light emitting region. surrounding region In FIG. 2, the infrared emitting unit 4 is disposed in a surrounding region located around the display region 10, more specifically, a non-display region. Not only the infrared emitting unit 4 but also drive circuits and the like (not shown) including active elements, such as transistors, can be disposed in the non-display region in order to perform appropriate display in the display region 10. In the present embodiment, the non-display region is provided so as to surround the display region 10; however, the non-display region is not limited thereto.

In FIG. 2, the light emitting apparatus 1 further includes the image capturing unit 5 for detecting reflected light (infrared reflected light) from the eye when infrared light emitted from the infrared emitting unit 4 (more specifically, the infrared light emitting elements 101) reaches the eye. The image capturing unit 5 includes a plurality of light receiving elements. The image capturing unit 5 including the light receiving elements just needs to include image pickup elements having sensitivity in the infrared range. For example, a photodiode, an organic photoelectric conversion element, an inorganic photoelectric conversion element, or the like may be selected as the light receiving element. The image capturing unit 5 may be formed on the same substrate with the display unit 3 and the infrared emitting unit 4 or may be formed on a different substrate as a separate member. It is possible to reduce erroneous detection due to incident visible light, so an infrared filter that transmits only infrared light may be provided on the image pickup elements or the light receiving elements.

The display light emitting element 100 may be formed by laminating a lower electrode (third electrode), a functional layer including a light emitting layer (second light emitting layer) or a light emitting substance, and an upper electrode (fourth electrode) on the substrate in this order from the substrate side. At this time, the light emitting layer or the light emitting substance may be configured to contain a chemical compound capable of emitting a light having a wavelength in the visible light range. The lower electrode and the upper electrode are referred to like that in accordance with their arrangement positions. In FIG. 3, the display light emitting element 100 is formed by laminating a lower electrode (second lower electrode) 12, a functional layer 13 including a light emitting layer (second light emitting layer), an upper electrode (second upper electrode) 14, a protective layer 15, a planarization layer 16, and a microlens 17 on the substrate 2 in this order. In FIG. 3, reference sign 18 indicates a pixel define layer (PDL) provided so as to cover a peripheral edge portion (both end portions in FIG. 3) of the lower electrode 12.

The pixel define layer 18 has an aperture portion formed such that part of the lower electrode 12 is exposed and is also called a partition wall, a bank, or the like. A part of the lower electrode 12, not in contact with the pixel define layer 18, may be in contact with the functional layer 13 including a light emitting layer. A region in which the lower electrode 12 and the functional layer 13 are in contact with each other is a light emitting region that emits light when an electric field is applied between the lower electrode 12 and the upper electrode 14. In the present embodiment, the lower electrode 12 and the functional layer 13 are in contact with each other at the aperture portion (hereinafter, which may be referred to as “image aperture region”) of the pixel define layer 18, and the aperture portion is the light emitting region 19. A pixel define layer may have a function to define a light emitting region of a light emitting element. In this case, a pixel define layer makes it possible to accurately form a light emitting region in a desired shape. In other words, a pixel aperture region can be regarded as a light emitting region. A pixel define layer may have a function to electrically insulate the lower electrodes of adjacent two light emitting elements from each other.

A light emitting region may be identified by viewing light emission during application of an electric field in a direction perpendicular to the principal surface of the substrate. A light emitting region may be identified by measuring a distance from one end of a pixel define layer covering the left edge end of a lower electrode to the other end of the pixel define layer covering the right edge end of the lower electrode. In a sectional view, as shown in FIG. 3, a light emitting region can be identified by measuring a distance from an end of one pixel define layer covering the left edge end of a lower electrode to an end of another pixel define layer covering the right edge end of the lower electrode. An end of a pixel define layer may be a contact between the pixel define layer and a lower electrode. When no pixel define layer is provided, a light emitting region can be defined in accordance with the shape of a lower electrode.

A plan view shape of the light emitting region 19 (the aperture portion of the pixel define layer 18) is not limited. For example, the plan view shape of the light emitting region 19 may be a circular or elliptical shape, or may be a polygonal shape, such as a hexagonal shape and a quadrangular shape, or may be another shape. Alternatively, a plurality of light emitting regions may be provided for one light emitting element by disposing a plurality of aperture portions of a pixel define layer such that the aperture portions are assigned to one light emitting element.

The infrared light emitting element 101 may be configured similarly to the display light emitting element 100. In other words, the infrared light emitting element 101 may be formed by laminating a lower electrode (first electrode), a functional layer including a light emitting layer (first light emitting layer) or a light emitting substance, and an upper electrode (second electrode) on the substrate in this order from the substrate side. At this time, the light emitting layer or the light emitting substance may be configured to contain a chemical compound capable of emitting a light having a wavelength in the infrared range. The lower electrode and the upper electrode are referred to like that in accordance with their arrangement positions. In FIG. 3, the infrared light emitting element 101 is formed by laminating a lower electrode (first lower electrode) 112, a functional layer 113 including a light emitting layer (first light emitting layer), an upper electrode (first upper electrode) 114, a protective layer 115, a planarization layer 116, and a microlens 117 on the substrate 2 in this order. In FIG. 3, reference sign 118 indicates a pixel define layer provided so as to cover a peripheral edge portion of the lower electrode 112. The pixel define layer 118 is as described above.

The upper electrode may be disposed separately for each light emitting element, or may be disposed astride the plurality of display light emitting elements 100 and the plurality of infrared light emitting elements 101 so as to be shared by the plurality of display light emitting elements 100 and the plurality of infrared light emitting elements 101. In other words, the entire surface of the display region 10 in FIG. 2 can be made up of a common upper electrode, that is, a single upper electrode can be disposed in the light emitting apparatus 1.

In the present embodiment, the functional layer including the light emitting layer, the upper electrode, the protective layer, and the planarization layer are shared by the plurality of display light emitting elements 100 and the infrared light emitting elements 101. The functional layer including the light emitting layer, the upper electrode, the protective layer, and the planarization layer may be shared by the plurality of light emitting elements or may be disposed separately for each light emitting element.

The lower electrode is disposed one by one for each display light emitting element 100 and each infrared light emitting element 101, and adjacent two of the lower electrodes are electrically insulated by the pixel define layer 18 or the pixel define layer 118.

A display light emitting element and an infrared light emitting element may have a so-called microcavity structure. When the display light emitting element 100 and the infrared light emitting element 101 have a microcavity structure in the present embodiment, where an optical path length from the upper surface of the lower electrode to a light emitting position of the functional layer is Lr and a phase shift at the time when light with a wavelength λ reflects on the interface of the lower electrode is Φr, the following formula (1) holds.

$$Lr = ( 2 m - ( Φ r / π ) ) \times ( λ / 4 ) \qquad ( 1 )$$

Here, m is an integer greater than or equal to zero. An optical distance of the functional layer can be optimized in each color such that the formula (1) is satisfied.

In the case of the wavelength λ that satisfies the formula (1), light in each color, emitted from the display light emitting element 100, is intensified, and, even when the wavelength λ within the range of a value shifted by ±λ/12 is used, light emitted from the display light emitting element 100 and light emitted from the infrared light emitting element 101 can be intensified. In other words, the wavelength λ that satisfies the following formula (2) may be adopted.

$$Lr = ( 2 m - ( Φ r / π ) ) \times ( λ / 4 ) \pm λ / 12 \qquad ( 2 )$$

Where an optical distance from a light emitting position of the functional layer to a reflection surface of the upper electrode 14 is Ls and a phase shift at the time when light with the wavelength λ reflects on the interface of the upper electrode is Φs, the following formula (3) holds. m′ is an integer greater than or equal to zero.

$$Ls = ( 2 {m}^{′} - ( Φ s / π ) ) \times ( λ / 4 ) = - ( Φ s / π ) \times ( λ / 4 ) \qquad ( 3 )$$

As in the case of the formula (1), in the case of the wavelength λ that satisfies the formula (3), light emitted from the display light emitting element 100 is intensified, and, even when the wavelength λ within the range of a value shifted by ±λ/12 is used, light emitted from the display light emitting element 100 can be intensified. In other words, in the present embodiment, the wavelength λ that satisfies the following formula (4) may be adopted.

$$\begin{matrix}Ls = ( 2 {m}^{′} - ( Φ s / π ) ) \times ( λ / 4 ) \pm λ / 12 \\ = - ( Φ s / π ) \times ( λ / 4 ) \pm λ / 12\end{matrix} \qquad ( 4 )$$

As a result, an all-layer interference L substantially satisfies the following formula (5).

$$L 1 = L r + L s = ( 2 m - Φ / π ) \times ( λ / 4 ) \qquad ( 5 )$$

Here, Φ is the sum Φr+Φs of a phase shift at the time when light with the wavelength A reflects on the interface of the lower electrode and a phase shift at the time when light with the wavelength λ reflects on the interface of the upper electrode.

Furthermore, the wavelength λ that satisfies the formula (5) is most intensified, and, even when the wavelength λ within the range of a value shifted by ±λ/12 is used, light emitted from the display light emitting element 100 and light emitted from the infrared light emitting element 101 can be intensified. In other words, in the present embodiment, the wavelength λ that satisfies the following formula (6) may be adopted.

$$L 1 = L r + L s = ( 2 m - Φ / π ) \times ( λ / 4 ) \pm λ / 12 \qquad ( 6 )$$

The optical distance may be varied between a display light emitting element and an infrared light emitting element. With such a configuration, a distance that intensifies visible light (display light) can be provided in the display light emitting element, and a configuration that intensifies infrared light emission can be provided in the infrared light emitting element.

With the above configuration, while the functional layer is shared among the display light emitting elements 100 and the infrared light emitting elements 101, visible light can be mainly emitted from the display light emitting elements 100, and infrared light can be emitted from the infrared light emitting elements 101.

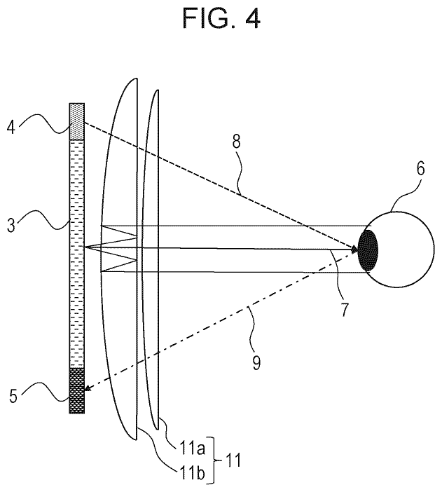

In the embodiment of the present disclosure, the light emitting apparatus 1 may be used together with an eyepiece optical system. In FIG. 4, the light emitting apparatus 1 is used together with an eyepiece optical system 11 to make up an image viewing apparatus. In FIG. 4, the continuous line arrow represents light (pencil of light rays) 7 that exits from the display unit 3 of the light emitting apparatus 1 and enters the eye 6 via the eyepiece optical system 11. The dashed line arrow represents light (pencil of light rays) 8 that exits from the infrared emitting unit 4 of the light emitting apparatus 1 and enters the eye 6 via the eyepiece optical system 11. The alternate long and short dashed line arrow represents light (pencil of light rays) 9 that is reflected from the eye 6 of a user. The eyepiece optical system 11 may be an optical member capable of guiding the display light 7 emitted from the display surface of the display unit 3 to the eye 6. The eyepiece optical system 11 may be an optical member including a polarization element, and a polarization element may be disposed between the eyepiece optical system 11 and the infrared emitting unit 4. In the present embodiment, the eyepiece optical system 11 is made up of a display lens. In FIG. 4, the display lens is a pancake lens made up of two lenses, that is, a lens 11a having a polarization-selective semi-transparent reflective element (PBS) or the like and a lens 11b having a semi-transparent reflective element or the like.

The display light (visible light) 7 and the infrared light 8 emitted from the light emitting apparatus 1 may be reached to the eye 6 of the user through the same eyepiece optical system 11. When the display light 7 is projected onto the eye 6 of the user, the viewer is able to view a display image. On the other hand, the infrared light 8 reflects on the eye 6 (more specifically, the cornea) of the user. Furthermore, infrared light (infrared reflected light) 9 reflected from the eye 6 of the user is converted to electrical information in the image capturing unit 5, and the line of sight is detected in accordance with the information.

In the display light emitting elements disposed in the display unit 3, luminance can be not decreased even when the eye 6 of the user moves or even when the viewing angle changes. On the other hand, in the infrared light emitting elements disposed in the infrared emitting unit 4, a certain amount of infrared light 9 reflected from the eye 6 of the user needs to be delivered to the image capturing unit 5. However, when the directivity of infrared light from the infrared emitting unit 4 is low, an amount of light delivered to the eye 6 reduces due to reflection and absorption with the optical lenses serving as the eyepiece optical system, so it is difficult to detect the visually recognizing point of the user.

In the present embodiment, since the light emitting apparatus 1 includes the microlenses 117 as lenses (first lenses) and includes the microlenses 17 as lenses (second lenses), the efficiency of extracting visible light and infrared light is improved. Therefore, an amount of visible light and an amount of infrared light increase, so it is possible to deliver a sufficient amount of visible light and infrared light to the eye 6 of the user.

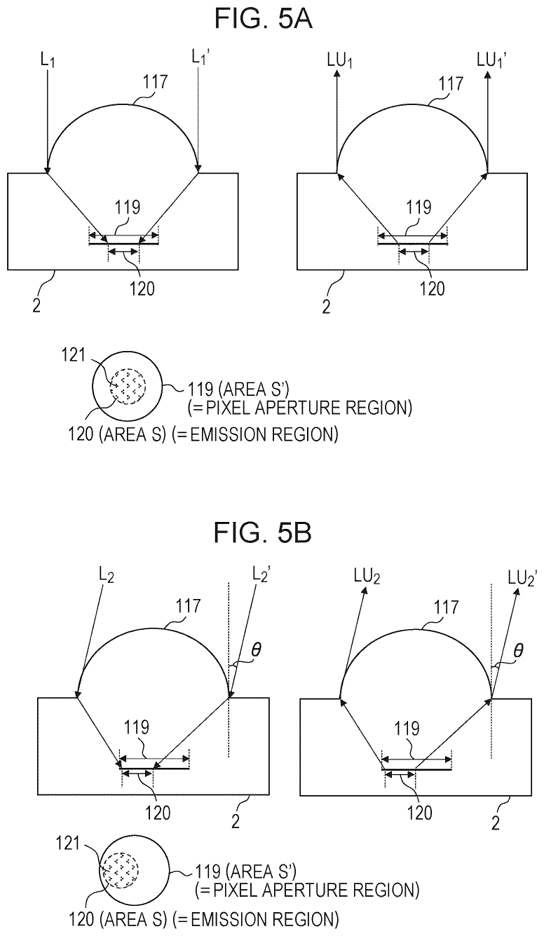

Next, extraction of light at the time when the light emitting element emits light in the present embodiment will be described with reference to FIGS. 5A and 5B. FIGS. 5A and 5B illustrate a case where the light emitting element is the first light emitting element; however, a similar configuration is applicable to the second light emitting element.

FIGS. 5A and 5B are sectional views that schematically show the light emitting element that is a component of the light emitting apparatus according to the embodiment of the present disclosure. In FIGS. 5A and 5B, part of the configuration of the light emitting element is omitted. Specifically, for the sake of convenience of description, only the substrate 2 and the microlens 117 and a light emitting region 119 disposed on the substrate 2 are shown and components other than these are omitted. Various members, such as electrodes other than the microlens 117 or the light emitting region 119 may be provided.

In FIGS. 5A and 5B, the light emitting element includes the substrate 2 and the microlens 117, and includes the light emitting region 119 between the substrate 2 and the microlens 117. The microlens 117 is disposed such that the curved surface part (convex side) protrudes toward a side opposite to the substrate, that is, a light exit side (light extraction side). The light emitting region 119 is a part of the functional layer, corresponding to the aperture portion of the pixel define layer 118, and light is emitted from this region. In the following description, a direction perpendicular to the principal surface of the substrate is referred to as “perpendicular direction (or normal direction)”, and a direction parallel to the principal surface of the substrate is referred to as “horizontal direction”.

Here, when the direction perpendicular to the substrate (perpendicular direction) is assumed as 0°, a light ray emitted from the light emitting region through the lens (first or second lens) and inclined at a selected angle with respect to the perpendicular direction, that is, a light ray in a direction opposite to light incidence may be referred to as “virtual light”. Virtual light incident through the lens (first or second lens) toward the light emitting region may be referred to as “virtual incident light”. This indicates an optical path of light (virtual light) traced in a direction opposite to light emission. Furthermore, a region that is formed such that virtual incident light reaches the light emitting region or the light emitting region and a surrounding part around the light emitting region (surrounding region) and intersects with the those regions may be referred to as “virtual light incident region”.

FIG. 5A shows entry and exit of light in the perpendicular direction. The top left view shows a state where virtual incident light passes through the lens (first lens) in the perpendicular direction and enters toward the light emitting region. Virtual incident light L₁, L₁′ reaches the light emitting region 119 through the lens 117 and intersects with the light emitting region 119 (the center of the light emitting region in the bottom left view) to form the virtual light incident region 120. The bottom left view shows the relationship between the virtual incident light and the light emitting region. The virtual light incident region 120 and the light emitting region 119 overlap each other to form a region (overlapping region) 121. In the bottom left view, the region surrounded by the continuous line represents the light emitting region 119, the region surrounded by the dashed line represents the virtual light incident region 120, and the filled-in area represents the overlapping region 121. The top right view shows a state where light is emitted from the light emitting region 119 through the lens in the perpendicular direction, and, when light is emitted from the light emitting region 119, the region 121 is a part (region) from which light (infrared light) LU₁, LU₁′ can be extracted. In other words, the virtual light incident region 120 is the same as an exit region of light (visible light or infrared light).

On the other hand, FIG. 5B shows entry and exit of light in a direction inclined at a selected angle θ with respect to the perpendicular direction. The top left view shows a state where virtual incident light passes through the lens (first lens) in the direction inclined at the selected angle θ with respect to the perpendicular direction and enters toward the light emitting region. Virtual incident light L₂, L₂′ reaches the light emitting region 119 through the lens 117 and intersects with the light emitting region 119 (the left side in the light emitting region in the bottom left view (on an opposite side to the side inclined with respect to the perpendicular direction)) to form the virtual light incident region 120. As in the case of FIG. 5A, the virtual light incident region 120 and the light emitting region 119 overlap to form the region (overlapping region) 121, and the region 121 is a part (region) from which light (infrared light) can be extracted at the time when light is emitted from the light emitting region 119. In other words, the virtual light incident region 120 is the same as an exit region of light.

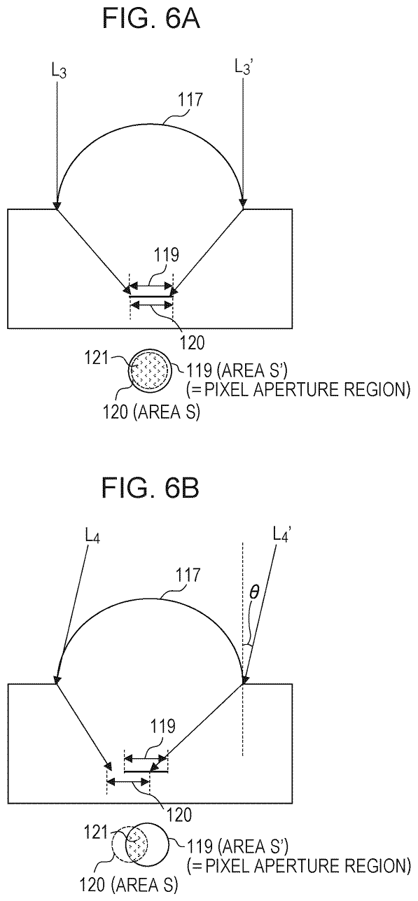

Furthermore, the effect of improving the directivity of light emitted from the light emitting element in the present embodiment will be described with reference to FIGS. 6A to 8B.

FIGS. 6A to 8B are schematic sectional views that show examples of the light emitting element that is a component of the light emitting apparatus according to the embodiment of the present disclosure. In FIGS. 6A to 8B, as in the case of FIGS. 5A and 5B, part of the configuration of the light emitting element is omitted. FIGS. 6A to 8B illustrate a case where the light emitting element is the first light emitting element; however, a similar configuration is applicable to the second light emitting element.

FIGS. 6A and 6B show a state (S/S′≈1) where, when the area of a region formed such that virtual light (virtual incident light) incident through the lens (first lens) reaches a light emitting region of the light emitting element (first light emitting element) or the light emitting region and a surrounding part around the light emitting region (surrounding region) is S and the area of the light emitting region of the light emitting element is S′, a ratio (S/S′) of the S to the S′ is close to one.

FIG. 6A shows a case where light is extracted in the perpendicular direction and shows a state where virtual incident light L₃, L₃′ passes through the lens (first lens) 117 in the perpendicular direction, reaches the light emitting region 119, and intersects with the light emitting region 119 (the center of the light emitting region in the bottom left view) to form the virtual light incident region 120. When the virtual light incident region 120 and the light emitting region 119 overlap each other and light is emitted from the light emitting region 119, the region (overlapping region) 121 that is a part (region) from which light (infrared light) can be extracted is formed. As shown in the bottom view of FIG. 6A, the virtual light incident region 120 and the light emitting region 119 substantially coincide with each other and substantially coincide with the overlapping region 121. In other words, the area of the overlapping region 121 is substantially equal to the area of each of the virtual light incident region 120 and the light emitting region 119. Therefore, when light is extracted in the perpendicular direction (from the front side), it is possible to efficiently extract a large amount of light, with the result that it is possible to deliver a sufficient amount of light to the eye of the user.

On the other hand, FIG. 6B shows a case where light is extracted in a diagonal direction, specifically, a direction inclined at a selected angle θ with respect to the perpendicular direction and shows a state where virtual incident light L₄, L₄′ passes through the lens (first lens) 117 in the direction inclined at the selected angle θ with respect to the perpendicular direction, reaches the light emitting region 119 and a surrounding part around the light emitting region 119, and the virtual light incident region 120 is formed so as to partially intersect with the light emitting region 119 (in the drawing, on the left side therein (on an opposite side to the side to which virtual incident light L₄, L₄′ is inclined))

Part of the virtual light incident region 120 and part of the light emitting region 119 overlap each other, and the region (overlapping region) 121 that is a part (region) from which light (infrared light) can be extracted when light is emitted from the light emitting region 119 is formed. As shown in the bottom view of FIG. 6B, the virtual light incident region 120 partially overlaps the light emitting region 119, and a large portion of the overlapping region 121 is located on the outer side. Therefore, it is not sufficient to efficiently extract light in the direction inclined at the angle θ with respect to the perpendicular direction, so it is found that viewing angle characteristics are slightly poor.

From above, according to the embodiment of the present disclosure, it is possible to improve the directivity, efficiency (extraction efficiency), and output of the light emitting element, and it is found that this is due to the fact that the ratio (S/S′) of the area S to the area S′ is close to one. S/S′ may be one. In other words, the area of the virtual light incident region and the area of the light emitting region may be equal to each other.

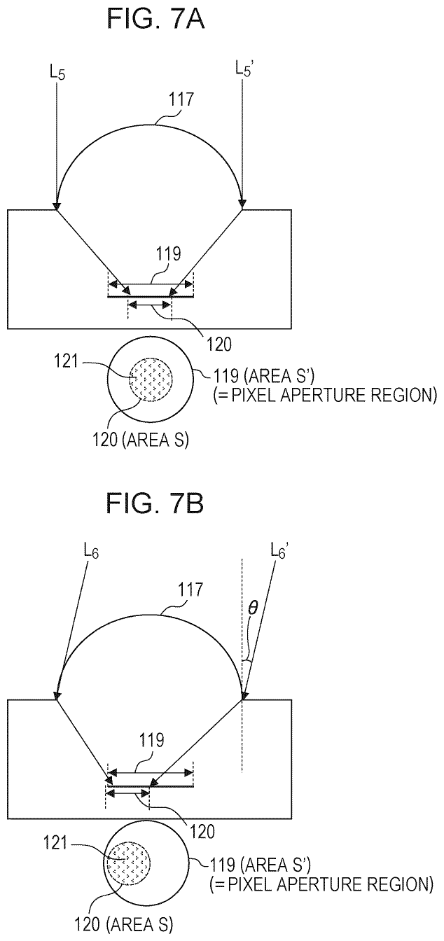

FIGS. 7A and 7B show a state (S/S′<1) where, when the area of a region formed such that virtual light (virtual incident light) incident through the lens (first lens) reaches the light emitting region of the light emitting element (first light emitting element) is S and the area of the light emitting region of the light emitting element is S′, the ratio (S/S′) of the S to the S′ is slightly farther (distant) from one than that of the configuration of FIGS. 6A and 6B because the S′ is larger than the S.

FIG. 7A shows a case where light is extracted in the perpendicular direction and shows a state where virtual incident light L₅, L₅′ passes through the lens (first lens) 117 in the perpendicular direction, reaches the light emitting region 119, and intersects with the inside (the center of the light emitting region in the view) of the light emitting region 119 to form the virtual light incident region 120. The region (overlapping region) 121 that is a part from which light (infrared light) can be extracted when the virtual light incident region 120 and the light emitting region 119 overlap each other and light is emitted from the light emitting region 119 is formed. As shown in the bottom view of FIG. 7A, the area(S) of the virtual light incident region 120 is smaller than the area (S′) of the light emitting region 119. In other words, the overlapping region 121, that is, a part (region) from which light can be extracted when light is emitted from the light emitting region 119, is smaller than the light emitting region 119. Therefore, the configuration of FIGS. 7A and 7B is presumably not sufficient in efficiently extracting light in the perpendicular direction as compared to the configuration of FIGS. 6A and 6B.

On the other hand, FIG. 7B shows a case where light is extracted in a diagonal direction, specifically, a direction inclined at a selected angle θ with respect to the perpendicular direction and shows a state where virtual incident light L₆, L₆′ passes through the lens (first lens) 117 in the direction inclined at the selected angle θ with respect to the perpendicular direction, reaches the light emitting region 119, and intersects with the left side (on an opposite side to the side to which the virtual incident light L₆, L₆′ is inclined) in the light emitting region 119 to form the virtual light incident region 120. The region (overlapping region) 121 that is a part from which light (infrared light) can be extracted when the virtual light incident region 120 and the light emitting region 119 overlap each other and light is emitted from the light emitting region 119 is formed. As shown in the bottom view of FIG. 7B, the overlapping region 121, that is, a part (region) from which light can be extracted when light is emitted from the light emitting region 119 is smaller than the light emitting region 119 as in the case of FIG. 7A. Therefore, it is presumably not sufficient to efficiently extract light in the direction inclined at the angle θ with respect to the perpendicular direction. As shown in the bottom view of FIG. 7B, the virtual light incident region 120 is in a state of completely included in the light emitting region 119. Therefore, it is found that the configuration of FIGS. 7A and 7B is advantageous in viewing angle characteristics.

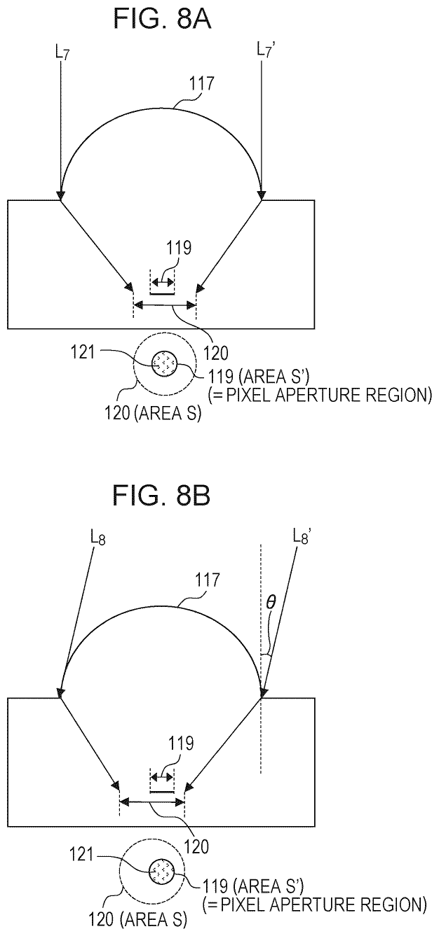

FIGS. 8A and 8B show a state (S/S′>1) where, when the area of a region formed such that virtual light (virtual incident light) incident through the lens (first lens) reaches the light emitting region of the light emitting element (first light emitting element) and a surrounding part around the light emitting region (surrounding region) is S and the area of the light emitting region of the light emitting element is S′, the ratio (S/S′) of the S to the S′ is slightly farther (distant) from one than that of the configuration of FIGS. 6A and 6B because the S′ is smaller than the S.

FIG. 8A shows a case where light is extracted in the perpendicular direction and shows a state where virtual incident light L₇, L₇′ passes through the lens (first lens) 117 in the perpendicular direction, reaches the light emitting region 119 and a surrounding part around the light emitting region 119, and intersects with the light emitting region 119 to form the virtual light incident region 120. In other words, the region (overlapping region) 121 that is a part from which light (infrared light) can be extracted when light is emitted from the light emitting region 119 is formed at a part overlapping the light emitting region 119 in the virtual light incident region 120. As shown in the bottom view of FIG. 8A, the area(S) of the virtual light incident region 120 is larger than the area (S′) of the light emitting region 119. In other words, the light emitting region 119 and the overlapping region 121 are smaller than a part (region) where light can be extracted with the lens 117. Therefore, the configuration of FIGS. 8A and 8B is presumably not sufficient in efficiently extracting light in the perpendicular direction as compared to the configuration of FIGS. 6A and 6B.

On the other hand, FIG. 8B shows a case where light is extracted in a diagonal direction, specifically, a direction inclined at a selected angle θ with respect to the perpendicular direction and shows a state where virtual incident light L₈, L₈′ passes through the lens (first lens) 117 in the direction inclined at the selected angle θ with respect to the perpendicular direction, reaches the light emitting region 119 and a surrounding part around the light emitting region 119, and intersects with the light emitting region 119 to form the virtual light incident region 120. In other words, the region (overlapping region) 121 that is a part from which light (infrared light) can be extracted when light is emitted from the light emitting region 119 is formed at a part overlapping the light emitting region 119 on the right side (on the side to which virtual incident light L₈, L₈′) is inclined) in the virtual light incident region 120. As shown in the bottom view of FIG. 8B, the light emitting region 119 and the overlapping region 121 are smaller than a part from which light can be extracted with the lens 117, as in the case of FIG. 8A. Therefore, it is presumably not sufficient to efficiently extract light in the direction inclined at the angle θ. As shown in the bottom view of FIG. 8B, the light emitting region 119 is in a state of completely included in the virtual light incident region 120. Therefore, it is found that the configuration of FIGS. 8A and 8B is advantageous in viewing angle characteristics.

From above, according to the embodiment of the present disclosure, it is possible to configure the light emitting element advantageous in viewing angle characteristics by configuring that the ratio (S/S′) of the S to the S′ is farther from one.

The ratio (S/S′) of S to S′ may be, for example, 0.7<S/S′<1.3. Preferably, 0.9<S/S′<1.1, and more preferably 0.95<S/S′<1.10.

In the embodiment of the present disclosure, where an area of a virtual light incident region formed such that virtual incident light passing through a lens (first lens) of an infrared light emitting element (first light emitting element) (which can be virtual incident light incident in a perpendicular direction) reaches a light emitting region of the infrared light emitting element or the light emitting region and a surrounding part around the light emitting region is S₁, an area of the light emitting region of the infrared light emitting element is S₁′, an area of a virtual light incident region formed such that virtual incident light passing through a lens (second lens) of a display light emitting element (second light emitting element) (which can be virtual incident light incident in the perpendicular direction) reaches a light emitting region of the display light emitting element or the light emitting region and a surrounding part around the light emitting region is S₂, and an area of the light emitting region of the display light emitting element is S₂′, a relationship that a ratio (S₁/S₁′) of the S₁ to the S₁′ is closer to one than a ratio (S₂/S₂′) of the S₂ to the S₂′ can be satisfied.

With such a configuration, viewing angle characteristics improve in light emission of the display unit (emission of visible light). Furthermore, directivity improves in light emission of the infrared emitting unit (emission of infrared light), with the result that it is possible to efficiently apply infrared light to the eye of the user.

Therefore, in the present embodiment, where the area of the virtual light incident region 120 formed such that virtual incident light passing through the lens 117 of the infrared light emitting element (first light emitting element) 101 (which can be virtual incident light incident in the perpendicular direction) reaches the light emitting region 119 of the infrared light emitting element 101 or the light emitting region 119 and a surrounding part around the light emitting region 119 is S₁, the area of the light emitting region 119 of the infrared light emitting element 101 is S₁′, the area of a virtual light incident region 20 formed such that virtual incident light passing through the lens (second lens) 17 of the display light emitting element (second light emitting element) 100 (which can be virtual incident light incident in the perpendicular direction) reaches the light emitting region 19 of the display light emitting element 100 or the light emitting region 19 and a surrounding part around the light emitting region 19 is S₂, and the area of the light emitting region of the display light emitting element 100 is S₂′, the relationship that the ratio (S₁/S₁′) of the S₁ to the S₁′ is closer to one than the ratio (S₂/S₂′) of the S₂ to the S₂′ can be satisfied.

In the present embodiment, for at least the infrared light emitting element, the ratio (S/S′) of S to S′ preferably satisfies the relationship that 0.7<S/S′<1.3 and, more preferably, satisfies the relationship that 0.9<S/S′<1.1.

In the present embodiment, where the area of a pixel aperture region of the infrared light emitting element (first light emitting element) 101 is R₁′ and the area of a pixel aperture region of the display light emitting element (second light emitting element) 100 is R₂′, the R₁′ may be smaller than the R₂′. In other words, R₁′<R₂′. With such a configuration, light output in the infrared light emitting element is more easily performed with high luminous efficiency than light output in the display light emitting element. This is because a lens, particularly, a microlens, generally has properties to condense light as a point from which the light is emitted approaches around the center of a pixel aperture region, light can be emitted in the perpendicular direction with a smaller amount of input current as the area of the pixel aperture region reduces, and it can be regarded that the light extraction efficiency is high. The area of the pixel aperture region is ordinarily equal to the area of the light emitting region. In other words, because R′=S′, R₁′=S₁′, and R₂′=S₂′, the relationship S₁′<S₂′ may be satisfied.

Because of a similar reason, the proportion of the area of the pixel aperture region in the infrared emitting unit 4 may be lower than the proportion of the area of the pixel aperture region in the display unit 3.

In the present embodiment, when the area of a bottom surface of the first lens (the microlens in the present embodiment) of the infrared light emitting element is T₁ and the area of a pixel aperture region of the infrared light emitting element is R₁′, while the area of a bottom surface of the second lens (the microlens in the present embodiment) of the display light emitting element is T₂ and the area of a pixel aperture region of the display light emitting element is R₂′, the ratio (R₁′/T₁) of the R₁′ to the T₁ may be less than the ratio (R₂′/T₂) of the R₂′ to the T₂. Here, a part where the height of a lens is minimum at a boundary with an adjacent lens can be regarded as an outer edge that defines a predetermined shape in a plan view. A surface defined by this outer edge can be understood as the bottom surface of the lens.

A lens, particularly, a microlens, has an operational effect to expand light from a pixel aperture region with a small area and emit the light. As R′/T reduces, the lens can emit light in the perpendicular direction with a smaller amount of input current, so the light extraction efficiency is high. Therefore, with the above configuration, by reducing the ratio (R₁′/T₁) in the infrared light emitting element as compared to the ratio (R₂′/T₂) in the display light emitting element, it is possible to increase the luminous efficiency of the infrared light emitting element in the perpendicular direction as compared to the display light emitting element.

In the present embodiment, the lens may be formed such that the inclination of its uppermost surface is close to a perpendicular angle. With such a configuration, light emitted in a diagonal direction from the light emitting region is more easily extracted from the front side, with the result that it is possible to further enhance directivity. Making the inclination of the uppermost surface of the lens be close to a perpendicular angle may be performed by, for example, a method of increasing the height of the lens as compared to the radial length, reducing the radial length of the lens as compared to the height, or the like, in a sectional view.

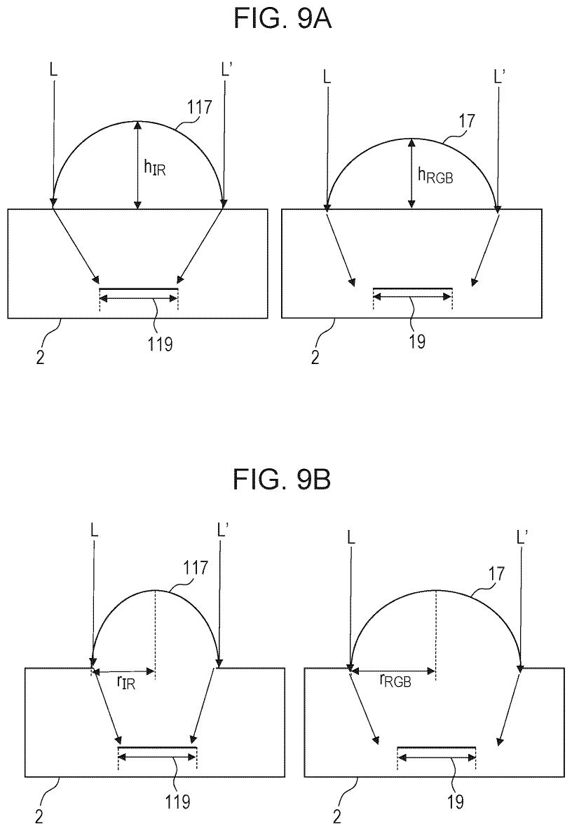

FIGS. 9A and 9B are schematic diagrams of an example of the light emitting element in the light emitting apparatus according to the embodiment of the present disclosure.

In FIG. 9A, when the lens height is a length from the middle point of the lens to the vertex of the lens (the length of a perpendicular from the vertex of the lens to a lens bottom surface), the lens height of the first lens of the infrared light emitting element is h_{IR}, and the lens height of the second lens of the display light emitting element is h_{RGB}, the inclination of the uppermost surface of the lens may be brought close to a perpendicular angle by increasing the h_{IR} as compared to the h_{RGB}.

As shown in FIG. 9B, when the lens radius is a length from the middle point of the lens to one end of a bottom portion, the lens radius of the first lens of the infrared light emitting element is r_{IR}, and the lens radius of the second lens of the display light emitting element is r_{RGB}, the inclination of the uppermost surface of the lens may be brought close to a perpendicular angle by reducing the r as compared to the r_{RGB}. The middle point of the lens here means a middle point between one end and the other end of the lens in a cross section passing through the vertex of the lens and perpendicular to the substrate.

### Second Embodiment

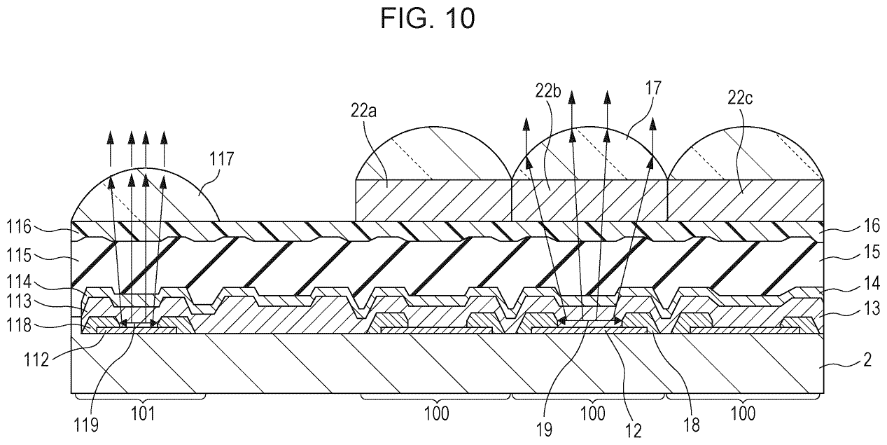

FIG. 10 is a schematic sectional view that shows an example of a light emitting apparatus according to a second embodiment of the present disclosure. The present embodiment differs from the first embodiment in that the light emitting apparatus 1 includes color filters. The remaining configuration is similar to that of the first embodiment.

In FIG. 10, color filters 22a to 22c are disposed on the planarization layer 16. In FIG. 10, pixels (display light emitting elements) respectively including the color filters 22a to 22c are assumed as sub-pixels, and these three sub-pixels may be regarded as one primary pixel. The colors of the sub-pixels are not limited. Three colors, that is, red, green, and blue, can be selected as the colors of the sub-pixels, and full-color display is achieved by additive color mixture of these sub-pixels. Rays of light emitted from the light emitting regions 19 pass through the color filters 22a to 22c to make it possible to increase color purity. A color filter, for example, a color filter that transmits infrared light, may be disposed in the infrared light emitting element 101.

By using the color filters, the ratio (S₁/S₁′) in the infrared light emitting element (first light emitting element) can be adjusted so as to be closer to one than the ratio (S₂/S₂′) in the display light emitting element (second light emitting element).

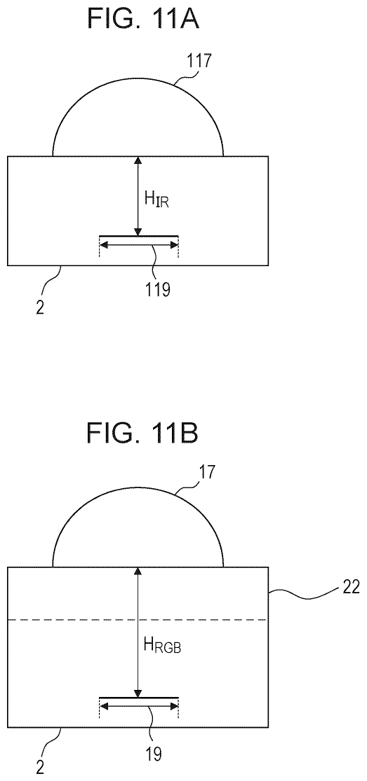

FIGS. 11A and 11B are sectional views that show an example of the light emitting apparatus according to the embodiment of the present disclosure. In FIG. 11B, the display light emitting element 100 has a color filter 22. On the other hand, in FIG. 11A, the infrared light emitting element 101 does not have a color filter. For this reason, the configuration of FIGS. 11A and 11B satisfies the relationship H_{IR}<H_{RGB} when a minimum height from the surface of the lower electrode 12 of the display light emitting element 100 to the bottom surface of the microlens 17 (the length of a perpendicular from the middle point of the microlens 17 to the surface of the lower electrode 12) is H_{RGB} and a minimum height from the surface of the lower electrode 112 of the infrared light emitting element 101 to the bottom surface of the microlens 117 (the length of a perpendicular from the middle point of the microlens 117 to the surface of the lower electrode 112) is H_{IR}. With such a configuration, the ratio (S₁/S₁′) in the infrared light emitting element can be more easily brought close to one than the ratio (S₂/S₂′) in the display light emitting element.

### Third Embodiment

Without changing the positional relationship between the center of the light emitting region of the infrared light emitting element (first light emitting element) and the vertex of the first lens, the positional relationship between the center of the light emitting region of the display light emitting element (second light emitting element) and the vertex of the second lens may be changed. For example, the vertex of the first lens of the infrared light emitting element may be disposed at a position that overlaps in a plan view the center of the light emitting region of the infrared light emitting element, and the vertex of the second lens of the display light emitting element may be caused not to overlap in a plan view the center of the light emitting region of the display light emitting element (the position of the vertex of the second lens of the display light emitting element may differ in a plan view from the position of the center of the light emitting region of the display light emitting element). A change of the positional relationship may be performed for at least one display light emitting element.

In the present embodiment, for improvement in the directivity of infrared light, the positional relationship between the center of the light emitting region of the display light emitting element disposed in the display unit 3 and the vertex of the lens (microlens) just above the light emitting region is changed from the one in the second embodiment. The remaining configuration is similar to that of the second embodiment.

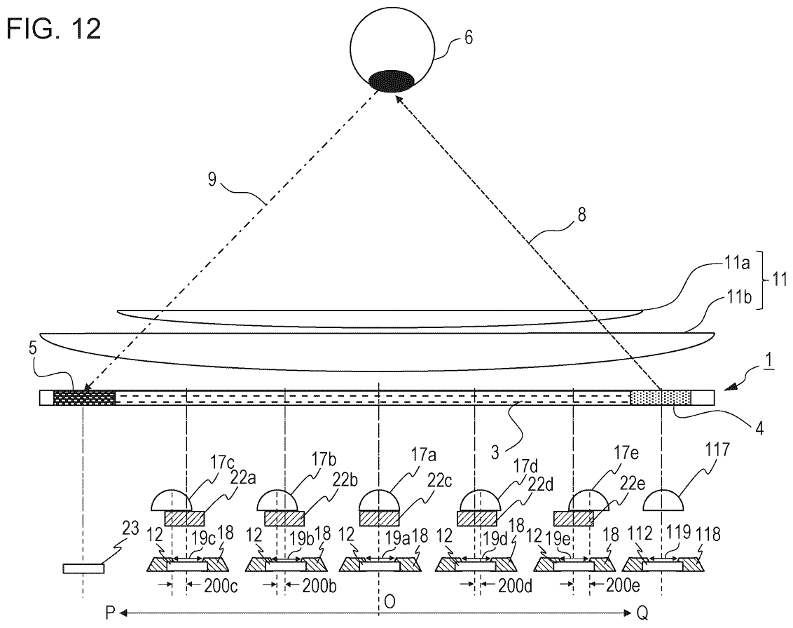

FIG. 12 is a schematic sectional view that shows an example of a light emitting apparatus according to the third embodiment of the present disclosure.

In FIG. 12, some of the light emitting elements and some of the light receiving elements are omitted. Specifically, only the lower electrodes 12, the pixel define layers 18, the microlenses 17, and the color filters 22 of some of the display light emitting elements 100 that make up the display unit 3, the lower electrode 112, the pixel define layer 118, and the microlens 117 of one of the infrared light emitting elements 101 that make up the infrared emitting unit 4, and a light receiving region 23 of one of the light receiving elements are shown, and some light emitting elements and light receiving elements disposed between the light emitting elements (pixels) are omitted for the sake of convenience.

The configuration of FIG. 12 is similar to the configuration of the second embodiment except that, in some of the display light emitting elements 100 disposed in the display unit 3, the lens (second lens) is made up of a symmetrical microlens and the lens is disposed in a state where the vertex is shifted from the center of the light emitting region. Here, the phrase “in a state where X is shifted from Y” means that X and Y do not overlap each other in a plan view when viewed in a direction perpendicular to the principal surface of the substrate and/or in a sectional view when a cross section perpendicular to the principal surface of the substrate is viewed and X and Y are in a state spaced apart with a certain distance.

When the light emitting region has a polygonal shape, the center of an inscribed circle of the polygon may be, for example, regarded as the center of the light emitting region. When the light emitting region has a circular or elliptical shape, the center of the circle or the ellipse may be regarded as the center of the light emitting region. Alternatively, the center of gravity of a figure defined by the outer edge of a region emitting light when a light emitting surface at the time of application of an electric field to the light emitting region is viewed in a direction perpendicular to the light emitting surface may be regarded as the center of the light emitting region. When viewed in a cross section perpendicular to the principal surface of the substrate, the middle point of the light emitting region may be regarded as the center of the light emitting region. In a sectional view, the middle point of the light emitting region may be a point on a line segment from the left end of the lower electrode to the right end of the lower electrode and is equidistant from both ends or a point on a line segment from one end of the pixel define layer covering the left edge end of the lower electrode to the other end of the pixel define layer covering the right edge end of the lower electrode and is equidistant from both ends.

In FIG. 12, the lens 117 disposed just above the light emitting region 119 is a symmetrical microlens, and the vertex is not in a state shifted from the center of the light emitting region 119. On the other hand, the lenses 17a to 17e respectively disposed just above the light emitting regions 19a to 19e are symmetrical microlenses, as in the case of the configuration of FIG. 10, and the microlenses 17b to 17e of those lenses are disposed such that the vertexes are respectively shifted from the centers of the light emitting regions 19b to 19e. In FIG. 12, the microlens 17a just above the light emitting region 19a is not disposed such that the vertex is shifted from the center of the light emitting region 19a; however, the microlens 17a may be disposed so as to be shifted from the point of the center O.

Specifically, in FIG. 12, the microlens 17b just above the light emitting region 19b is disposed in a state where the vertex is shifted by a shift amount 200b in a sectional view in a direction from the center O of the light emitting apparatus 1 toward an outer side P (toward the left-hand side in FIG. 12) from the center of the light emitting region 19b. Similarly, the microlens 17c just above the light emitting region 19c is disposed in a state where the vertex is shifted in a direction by an amount 200c in a direction from the center O of the light emitting apparatus 1 toward the outer side P from the center of the light emitting region 19c. The microlens 17d just above the light emitting region 19d is disposed in a state where the vertex is shifted by an amount 200d in a direction from the center O of the light emitting apparatus 1 toward an outer side Q (toward the right-hand side in FIG. 12) from the center of the light emitting region 19d. The microlens 17e just above the light emitting region 19e is disposed in a state where the vertex is shifted by an amount 200e in a direction from the center O of the light emitting apparatus 1 toward the outer side Q (toward the right-hand side in FIG. 12) from the center of the light emitting region 19e. In other words, in FIG. 12, of the microlenses disposed in the display unit 3, the microlenses 17d, 17e disposed at the outer side of the light emitting apparatus 1 differ in the shift direction from the microlenses 17d, 17e.

Therefore, in a center region located at the central part of the display region 10, light rays traveling in the normal direction (toward the front side) with respect to the display surface are used. On the other hand, in a peripheral region located at a peripheral part of the display region 10, that is, a region in which the display light emitting elements disposed on the outer side are present, light rays bent in a diagonal direction with respect to the normal direction of the display surface are used, and the light rays enter the eye 6 of the user to form an image. As a result, in the peripheral region, the efficiency of extracting visible light that is emitted in a diagonal direction with respect to the normal direction of the display surface improves.

A change of the positional relationship between the center of the light emitting region and the vertex of the lens (microlens) just above the light emitting region may be performed by using an asymmetrical lens (such as a lens of which the center (the center of gravity of a shape formed by a line connecting the ends of the lens in a plan view) deviates from the vertex) as the lens disposed just above the light emitting region.

The color filters 22a to 22e, as in the case of the microlenses 17, may be respectively disposed in a state of being shifted from the centers of the light emitting regions 19a to 19e.

A light receiving unit configured to be capable of receiving infrared light that is emitted from the infrared light emitting element, more specifically, infrared light that is emitted from the infrared light emitting element and reflected from the eye may be provided. Specifically, in the image capturing unit 5, the light receiving region 23 that receives infrared light emitted from the infrared light emitting element may be disposed. At this time, a lens (third lens) may be disposed above the light receiving region 23, and the vertex of the lens may be disposed in a state of being shifted from the light receiving region 23 (for example, its center).

According to the present embodiment, it is possible to enhance the directivity of the infrared light emitting element and efficiently deliver light to the image capturing unit (particularly, its light receiving region) without reducing the display quality of the display light emitting element.

### [Configuration of Light Emitting Element]

In the light emitting element according to the embodiment of the present disclosure, an insulating layer, a lower electrode, a functional layer including a light emitting layer, and an upper electrode can be provided on a substrate. A protective layer, a color filter, a microlens, or the like may be provided on the upper electrode. When the color filter is provided, a planarization layer may be provided between the color filter and the protective layer. The planarization layer may be made of acrylic resin or the like. This also applies to a case where the planarization layer is provided between the color filter and the microlens.

### Substrate

The substrate that is a component of the light emitting element is made up of a sheet-like member having a principal surface. The substrate may be a semiconductor substrate, such as a silicon substrate, or may be an insulating substrate made of glass, quartz, resin, or the like. The substrate may have flexibility. The material of the substrate includes at least one of quartz, glass, silicon, resin, and metal. The substrate may include a switching element, such as a transistor, and a wire. The substrate itself may have an insulation property or insulating layer (insulating film) may be provided on the substrate. Insulating Layer

An insulating layer (insulating film) may be provided on the substrate. The insulating layer may be made of any material as long as a contact hole can be formed such that a wire can be formed between the insulating layer and the lower electrode (a first electrode or a third electrode) and insulation from a non-connected wire can be ensured. The insulating layer may be made of an inorganic material, such as silicon nitride (SiN), silicon oxynitride (SiON), and silicon oxide (SiO). A known technique, such as a sputtering method and a chemical vapor deposition method (CVD method), may be used to form the insulating layer. Alternatively, the insulating layer may be made of an organic material, such as acrylic resin and polyimide resin.

### Electrodes

A pair of electrodes may be used as the electrodes of the light emitting element. The pair of electrodes may be an anode and a cathode. When an electric field is applied in a direction in which the light emitting element emits light, the electrode having a higher potential is an anode, and the other electrode is a cathode. In other words, the electrode that supplies holes to a light emitting layer or a light emitting substance is an anode, and the electrode that supplies electrons is a cathode. In the present embodiment, the lower electrode (a first electrode and a third electrode) is an anode, and the upper electrode (a second electrode and a fourth electrode) is a cathode (light extraction electrode); however, the lower electrode may be a cathode, and, in this case, the upper electrode is an anode.

### Anode

A component material of the anode can be the one with a work function that is as large as possible. For example, a metal chemical element, such as gold, platinum, silver, copper, nickel, palladium, cobalt, selenium, vanadium, and tungsten, or a mixture containing one or some of these metal chemical elements may be used for the anode. Alternatively, an alloy made of a combination of some of these metal chemical elements, or a metal oxide, such as a tin oxide, a zinc oxide, an indium oxide, an indium tin oxide (ITO), and an indium zinc oxide, may be used for the anode. A conductive polymer, such as polyaniline, polypyrrole, and polythiophene, may be used for the anode.

Any one of these electrode materials may be used solely or two or more types of these materials may be used together. The anode may be made up of one layer or may be made up of a plurality of layers.

When the electrode is used as a reflecting electrode, for example, chromium, aluminum, silver, titanium, tungsten, molybdenum, an alloy of some of these materials, a laminate of some of these materials, or the like may be used as the electrode material. The above materials may be used to function as a reflective film that does not serve as an electrode. When used as a transparent electrode, a transparent conductive oxide layer of an indium tin oxide (ITO), an indium zinc oxide, or the like may be used; however, the material is not limited thereto. Photolithography may be used to form electrodes.

### Cathode

On the other hand, the component material of the cathode can be the one with a small work function. Examples of the component material of the cathode include alkali metals, such as lithium, alkaline earth metals, such as calcium, metal chemical elements, such as aluminum, titanium, manganese, silver, lead, and chromium, and mixtures containing one or some of these metal chemical elements. Alternatively, an alloy made of a combination of some of these metal chemical elements may be used. For example, magnesium-silver, aluminum-lithium, aluminum-magnesium, silver-copper, zinc-silver, or the like may be used. A metal oxide, such as an indium tin oxide (ITO), may also be used. One type of these electrode materials may be used solely or two or more types of these electrode materials may be used together. The cathode may be made up of a single layer or may be made up of multiple layers. Among others, silver can be used, and a silver alloy can be further used to reduce aggregation of silver. As long as aggregation of silver is reduced, the ratio of an alloy does not matter. For example, the ratio of silver to another metal may be one to one, three to one, or the like.

A cathode may be made as a top emission element by using an oxide conductive layer made of ITO or the like or may be made as a bottom emission element by using a reflecting electrode made of aluminum (Al) or the like. The arrangement of the cathode is not limited. A method of forming the cathode is not limited. When a direct-current sputtering method, an alternating-current sputtering method, or the like is used, the film has a good coverage, and it is easy to reduce the resistance, so it is more desirable.

The upper electrode may be disposed separately for each light emitting element, or may be disposed astride the plurality of light emitting elements 100 and the plurality of infrared light emitting elements 101 so as to be shared by the plurality of display light emitting elements 100 and the plurality of infrared light emitting elements 101. The entire surface of the display region 10 can be made up of a common upper electrode, that is, a single upper electrode can be disposed in the light emitting apparatus 1.

### Organic Compound Layer as Functional Layer

An organic compound layer as the functional layer includes a light emitting layer containing a light emitting substance and is disposed on the lower electrode. The organic compound layer can be formed by using a known technique, such as a vapor deposition method and a spin coating method. An organic compound layer may be made up of a single layer or may be made up of a plurality of layers. A plurality of layers may include a hole injection layer, a hole transport layer, an electron blocking layer, a light emitting layer, a hole blocking layer, an electron transport layer, an electron injection layer, and the like. Another layer, such as a charge generation layer and an electron block layer, may be included between these layers.

The organic light emitting element emits light in a manner such that holes injected from an anode and electrons injected from a cathode recombine in the light emitting layer. The light emitting layer may be made of an inorganic compound, may be made of an organic compound, or may be made of both. When the light emitting layer is made of an organic compound, the light emitting apparatus may be referred to as an “organic light emitting apparatus”, and the light emitting element may be referred to as an “organic light emitting element”. The organic compound layer just needs to be mainly made of an organic compound and may include inorganic atoms or an inorganic compound. The organic compound layer may include, for example, copper, lithium, magnesium, aluminum, iridium, platinum, molybdenum, zinc, or the like. When the light emitting layer or the light emitting substance in the organic compound layer of the display light emitting element is organic, that is, when the display light emitting element is made up of an organic light emitting element, the infrared light emitting element can also be an organic light emitting element. In this case, the display light emitting element and the infrared light emitting element can be manufactured in the same process.

The organic compound layer may be disposed between the lower electrode and the upper electrode and may be disposed in contact with the lower electrode and the upper electrode.

A light emitting material used to form the light emitting layer may be a material, such as a fluorescent material, a phosphorescent material, and a delayed fluorescent material, or may be a quantum dot, such as CdS and perovskite. The light emitting substance may be a substance that is a component of these materials and quantum dots. The light emitting layer may be made up of multiple layers or may be made up of a single layer. When there is a light emitting layer made up of multiple layers, a red light emitting material, a green light emitting material, and a blue light emitting material can be contained in layers of the light emitting layer. White light can be obtained by mixing light emitting colors. Light emitting materials of complementary colors, such as a blue light emitting material and a yellow light emitting material, may be contained in organic compound layers. Light in a different color may be emitted by changing materials contained in the light emitting layer and the configuration of the light emitting layer for each light emitting pixel.

When an organic compound layer capable of emitting light in a wavelength range of a visible to infrared range is selected as an organic compound layer, the display light emitting elements 100 and the infrared light emitting elements 101 may have one light emitting layer. In other words, the plurality of display light emitting elements and the plurality of infrared light emitting elements may share one light emitting layer. On the other hand, a light emitting layer may be provided one by one for each of the display light emitting elements and the infrared light emitting elements. In this case, a light emitting layer may be patterned for each of the light emitting elements 100 and the infrared light emitting elements 101.

### Organic Compound Layer

When the functional layer including the light emitting layer is an organic compound layer, the organic compound layer (such as a hole injection layer, a hole transport layer, an electron blocking layer, a light emitting layer, a hole blocking layer, an electron transport layer, and an electron injection layer) can be formed by using a dry process, such as a vacuum evaporation method, an ionized evaporation method, a sputtering method, and a plasma method. Instead of the dry process, a wet process in which a layer is formed with a known coating method (such as spin coating, dipping, a casting method, an LB method, and an ink-jet method) by dissolving an organic compound in an appropriate solvent may be used. When a layer is formed with a vacuum evaporation method, a solution coating method, or the like, crystallization or the like is less likely to occur, and it is excellent in temporal stability. When a film is formed with a coating method, the film may be formed in combination with an appropriate binder resin.

The binder resin may be polyvinyl carbazole resin, polycarbonate resin, polyester resin, ABS resin, acrylic resin, polyimide resin, phenolic resin, epoxy resin, silicon resin, urea resin, or the like; however, the binder resin is not limited to these materials. One type of these binder resins may be used solely as a homopolymer or a copolymer or two or more types of these binder resins may be mixed and used. Furthermore, as needed, an additive, such as a known plasticizer, a known oxidation inhibitor, and a known ultraviolet absorbent, may be used together.

### Pixel Define Layer

A pixel define layer (PDL) is made up of a silicon nitride (SiN) film, a silicon oxynitride (SiON) film, or a silicon oxide (SiO) film formed with a chemical vapor deposition method (CVD method). To increase the resistance of the functional layer, particularly, the resistance in an in-plane direction of an organic compound layer, the organic compound layer, particularly, the hole transport layer can be formed thin at a side wall of the pixel define layer. Specifically, an eclipse during vapor deposition is increased by reducing a taper angle of a side wall of the pixel define layer or increasing the film thickness of the pixel define layer, with the result that the film thickness of the side wall can be made thin.

On the other hand, the side wall taper angle of the pixel define layer or the film thickness of the pixel define layer can be adjusted to such an extent that no air gap is formed in the protective layer formed on the pixel define layer. Since no air gap is formed in the protective layer, it is possible to reduce occurrence of defects in the protective layer. Since occurrence of defects in the protective layer is reduced, it is possible to reduce a decrease in reliability, such as occurrence of a dark spot and occurrence of poor conduction of the upper electrode.

According to the present embodiment, even when the taper angle of the side wall of the pixel define layer is not steep, it is possible to effectively suppress leakage of electric charge to an adjacent pixel. As a result of study made by the inventor, it is found that leakage of electric charge can be sufficiently reduced when the taper angle falls within the range larger than or equal to 60 degrees and smaller than or equal to 90 degrees. The film thickness of the pixel define layer is desirably greater than or equal to 10 nm and less than or equal to 150 nm. A similar effect is obtained even with a configuration including only a pixel electrode and not including a pixel define layer. However, in this case, a short circuit of the light emitting element, particularly, the organic light emitting element, can be reduced by setting the film thickness of the pixel electrode to a half of the functional layer or less or forming a pixel electrode end in a forward tapered shape with an angle smaller than 60 degrees.

### Protective Layer

A protective layer may be provided on the upper electrode in the light emitting element. For example, when glass provided with a humectant is bonded onto the second electrode, entry of water or the like to the functional layer, particularly, the organic compound layer, is reduced, so it is possible to reduce occurrence of poor display. In another embodiment, a passivation film made of silicon nitride or the like may be provided on a cathode to reduce entry of water or the like to the functional layer. For example, the protective layer may be provided by conveying the cathode after being formed to another chamber without breaking a vacuum and forming a 2-μm-thick silicon nitride film by CVD. After deposition with CVD, a protective layer using atomic layer deposition (ALD) may be provided. The material of the film formed by ALD is not limited and may be a silicon nitride, a silicon oxide, an aluminum oxide, or the like. A silicon nitride may be formed by CVD further on the film formed by ALD. The film thickness of the film formed by ALD may be less than the film thickness of the film formed by CVD. Specifically, the film thickness of the film formed by ALD may be less than or equal to 50% of the film thickness of the film formed by CVD and, furthermore, may be less than or equal to 10% of the film thickness of the film formed by CVD. The protective layer may be disposed over a plurality of display elements and a plurality of infrared light emitting elements.

### Formation of Electrode or Layer Between Light Emitting Elements

When there is a common electrode or layer between one light emitting element and the other light emitting element, the electrode or layer may be disposed astride the one light emitting element and the other light emitting element as long as no adverse effect is given to the light extraction structure. For example, the upper electrode may be shared by the plurality of display light emitting elements 100 and the plurality of infrared light emitting elements 101. The entire surface of the display region 10 may be made up of a common upper electrode.

### Color Filter

A color filter may be provided on the protective layer in the light emitting element. For example, color filters designed in consideration of the size of each light emitting element may be provided on another substrate, and the substrate may be bonded to a substrate on which the light emitting elements are provided. Alternatively, color filters may be patterned on the above-described protective layer by using photolithography. A color filter may be made of a high polymer. For example, a color filter may be provided above the light receiving region in the light receiving element.

As for a color filter, when the color filter is viewed in a cross section perpendicular to the principal surface of the substrate, the middle point of the color filter can be regarded as the center of the color filter.

### Planarization Layer

When a color filter is provided on the protective layer in the light emitting element, a planarization layer (planarizing film) may be provided between the color filter and the protective layer. The planarization layer is provided for the purpose of reducing the irregularities of the lower layer. When the purpose is not limited, the planarization layer may be referred to as a resin layer. The planarization layer may be made of an organic compound and may be a low-molecular compound or a macromolecular compound. The planarization layer can be a macromolecular compound.

The planarization layer may be provided on the upper and lower sides of the color filter, and the component materials of those layers may be the same or may be different. Specifically, the planarization layer may be polyvinyl carbazole resin, polycarbonate resin, polyester resin, ABS resin, acrylic resin, polyimide resin, phenolic resin, epoxy resin, silicon resin, urea resin, or the like.

### Lens

The light emitting element may include an optical member, such as a lens, on its light emission side, for example, on the planarization layer.

The light receiving element may also include a lens on the upper side, for example, on an incident side of light (light to be received). The lens may be provided on a light extraction side of the light emitting apparatus, and the lens may be convex toward the light extraction side. In other words, the lens may be convex toward a side opposite from the substrate or may be convex toward a substrate side.

The lens may be an optical member, including a so-called microlens. The lens can be made of acrylic resin, epoxy resin, or the like. The lens may be provided for the purpose of increasing the amount of light extracted from the light emitting element and controlling the direction in which light is extracted.

The lens is not limited to a spherical lens and may be an aspherical lens, an asymmetrical lens, or a digital microlens. The lens may be a lens with a small diameter. The lens may have a hemispherical shape. When the lens has a hemispherical shape, there is a tangent parallel to the principal surface of the substrate among tangents that are tangent to the hemisphere, and a point of contact between the parallel tangent and the hemisphere is the vertex of the lens. The vertex of the lens can be similarly determined even in a selected sectional view. In other words, there is a tangent parallel to the principal surface of the substrate among tangents that are tangent to a semicircle of the lens in the sectional view, and a point of contact between the parallel tangent and the semicircle is the vertex of the lens. When the lens has a lens shape made up of a curved surface, such as an elliptic lens other than a hemispherical lens, and a parabolic lens, as well, the vertex of the lens can be similarly defined.

The middle point of the lens can be defined. In the cross section of the lens, a line segment from a point at which a circular arc shape ends (substantially the same as one end of the lens) to another point at which the circular arc shape ends (substantially the same as the other end of the lens) is assumed, and the middle point of the line segment can be called as the middle point of the lens. A cross section to determine a vertex or a middle point may be a cross section perpendicular to the principal surface of the substrate.

The lens has a first surface having a convex portion and a second surface opposite to the first surface. The second surface can be disposed on the functional layer side with respect to the first surface. To provide such a configuration, the lens needs to be formed on the light emitting element. When the functional layer is an organic compound layer, a process accompanied by high temperature can be avoided in a manufacturing process. Furthermore, when the functional layer is an organic compound layer and the second surface is disposed on the organic compound layer side with respect to the first surface, all the glass transition temperatures of organic compounds that make up the organic compound layer are preferably higher than or equal to 100° C. and more preferably higher than or equal to 130° C.

### Counter Substrate

In the light emitting apparatus according to the embodiment of the present disclosure, a counter substrate may be disposed on the planarization layer.

Because the counter substrate is provided at a position so as to face the above-described substrate, it is called a counter substrate. The component material of the counter substrate may be the same as that of the substrate. When the substrate is a first substrate, the counter substrate may be a second substrate.

### Pixel Circuit

The light emitting apparatus according to the embodiment of the present disclosure may include pixel circuits connected to the light emitting elements. The pixel circuits may be of an active matrix type that independently controls one light emitting element and another light emitting element. The active-matrix circuit may operate in accordance with voltage programming or current programming. The drive circuit has a pixel circuit for each pixel. The pixel circuit may include a light emitting element, a transistor that controls the emission luminance of the light emitting element, a transistor that controls light emission timing, a capacitor that holds the gate voltage of the transistor that controls the emission luminance, and a transistor for connection with a GND without intervening the light emitting element.

The light emitting apparatus according to the embodiment of the present disclosure may include a display region and a surrounding region (non-display region) disposed around the display region. Pixel circuits can be disposed in the display region, and a display control circuit can be disposed in the surrounding region. The mobility of a transistor that is a component of the pixel circuit may be smaller than the mobility of a transistor that is a component of the display control circuit. The slope of the current-voltage characteristics of a transistor that is a component of the pixel circuit may be smaller than the slope of the current-voltage characteristics of a transistor that is a component of the display control circuit. The slope of the current-voltage characteristics can be measured in accordance with so-called Vg-Ig characteristics. A transistor that is a component of the pixel circuit is a transistor connected to the light emitting element, such as one light emitting element.

### Pixel

The light emitting apparatus according to the embodiment of the present disclosure may have a plurality of pixels. Each pixel may have sub-pixels that emit light in different colors from each other, that is, display light emitting elements. The sub-pixels may respectively have, for example, RGB light emitting colors. The pixel emits light in a region also called a pixel aperture. This region is the same as a first region. The pixel aperture may be less than or equal to 15 μm and may be greater than or equal to 5 μm. More specifically, the pixel aperture may be 11 μm, 9.5 μm, 7.4 μm, 6.4 μm, or the like. An interval between the sub-pixels may be less than or equal to 10 μm and, specifically, may be 8 μm, 7.4 μm, or 6.4 μm.

The pixels can take a known arrangement mode in a plan view. The pixels may be arranged in, for example, a stripe array, a delta array, a pentile array, or a Bayer array. The shape of each sub-pixel in a plan view may be any one of known shapes. The shape of each sub-pixel in a plan view is, for example, a quadrangular shape, such as a rectangular shape and a rhombic shape, a hexagonal shape, or the like. When the shape of each sub-pixel is a shape close to, for example a rectangular shape, the shape is assumed to be included in a rectangular shape. Therefore, the shape of each sub-pixel just needs to be a shape approximated to the any one of known shapes. The pixels may be configured by combining the shape of each sub-pixel with a pixel array.

### [Uses of Light Emitting Apparatuses According to Embodiments of Present Disclosure]

The light emitting apparatuses according to the embodiments of the present disclosure each may be used as a component member of a display apparatus or a component member of an illumination apparatus. Other than those, there are uses, such as an exposure light source of an electrophotographic image forming apparatus and a light emitting apparatus including a color filter for a backlight or white light source of a liquid crystal display apparatus.

A display apparatus may be an image information processing apparatus. The image information processing apparatus includes an image input unit that enters image information from an area CCD, a linear CCD, a memory card, or the like, and an information processing unit that processes input information. The image information processing apparatus displays the input image on a display unit.

A display unit of an image capturing apparatus or ink-jet printer may have a touch panel function. A drive system of the touch panel function may be an infrared radiation method, a capacitance method, a resistive film method, or an electromagnetic induction method and is not limited. A display apparatus may be used as a display unit of a multifunction printer.

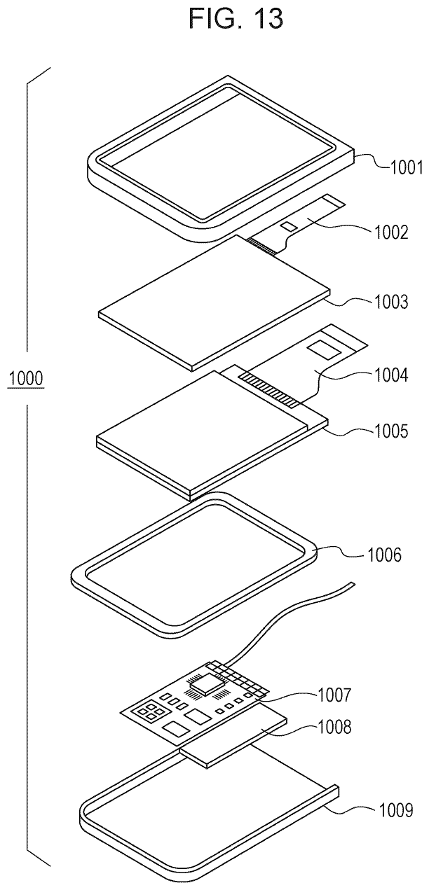

Hereinafter, application examples of the light emitting apparatus will be described with reference to FIGS. 13 to 16B.

FIG. 13 is a schematic view that shows an example of a display apparatus using the light emitting apparatus according to the present embodiment. The display apparatus 1000 may include a touch panel 1003, a display panel 1005, a frame 1006, a circuit board 1007, and a battery 1008 between a top cover 1001 and a bottom cover 1009. A flexible printed circuit (FPC) 1002 is connected to the touch panel 1003. A flexible printed circuit (FPC) 1004 is connected to the display panel 1005. Active elements, such as transistors, can be disposed on the circuit board 1007. In FIG. 13, transistors are printed on the circuit board 1007. The battery 1008 does not need to be provided when the display apparatus is not a mobile device, or may be provided at another position even when the display apparatus is a mobile device. The light emitting apparatus according to the present embodiment may be used as the display panel 1005. The display region (light emitting region) of the light emitting apparatus that functions as the display panel 1005 is connected to active elements, such as transistors, disposed on the circuit board 1007 and operates.

The display apparatus may include red, green, and blue color filters. The red, green, and blue color filters may be arranged in a delta array.

The display apparatus may be used in a display unit of a mobile terminal. In this case, the display apparatus may have a display function and an operating function. The mobile terminal may be a cellular phone, such as a smartphone, a tablet, a head mounted display, or the like.

The display apparatus using the light emitting apparatus according to the present embodiment may be used in a display unit of an image capturing apparatus including an optical unit having a plurality of lenses and image pickup elements that receive light passing through the optical unit.

The image capturing apparatus may include a display unit that displays information acquired by the image pickup elements. The display unit may be a display unit exposed to the outside of the image capturing apparatus or may be a display unit disposed in a viewfinder. The image capturing apparatus may be a digital camera or a digital camcorder.

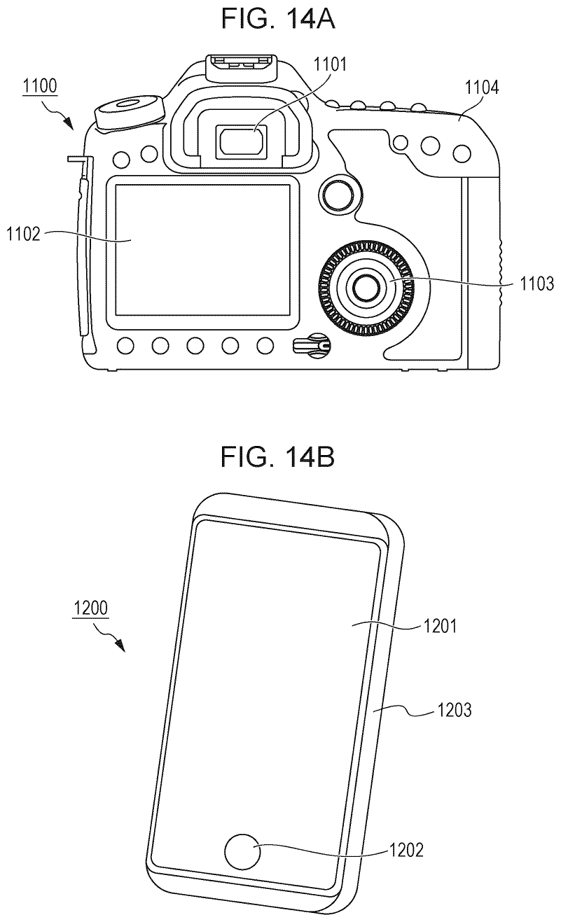

FIG. 14A is a schematic view that shows an example of an image capturing apparatus using the display apparatus according to the present embodiment. An image capturing apparatus 1100 may include a viewfinder 1101, a back display 1102, an operating portion 1103, and a housing 1104. The light emitting apparatus according to the present embodiment is applicable to the viewfinder 1101 or the back display 1102, which is the display unit. In this case, the display region (light emitting region) of the light emitting apparatus may display not only an image to be captured but also environmental information, an image capturing instruction, and the like. The environmental information may include the intensity of external light, the direction of external light, the moving speed of a subject, a possibility that a subject is shielded by a shielding material, or the like.

Since suitable timing for imaging is mostly a slight amount of time, information is desirably displayed as early as possible. Therefore, the light emitting apparatus in which the light emitting elements using organic light emitting material, such as organic EL elements, that is, the organic light emitting elements are disposed in the display region (light emitting region) can be used for the viewfinder 1101 or the back display 1102. This is because an organic light emitting element has a higher response speed. The light emitting apparatus using organic light emitting elements is more suitably used than a liquid crystal display apparatus for these apparatuses of which a higher display speed is desired.

The image capturing apparatus 1100 includes an optical unit (not shown). The optical unit has a plurality of lenses and forms an image on the image pickup elements accommodated in the housing 1104. The plurality of lenses is capable of adjusting a focal point by adjusting the relative positions of the lenses. This operation can be automatically performed. The image capturing apparatus may be called a photoelectric conversion apparatus. The photoelectric conversion apparatus can include not sequentially capturing an image but a method of detecting a difference from a previous image, a method of extracting an image from an image being constantly recorded, or the like, as a method of capturing an image.

The light emitting apparatus according to the present embodiment may be applied to a display unit of an electronic device. In this case, the light emitting apparatus may have a display function and an operating function. The mobile terminal may be a cellular phone, such as a smartphone, a tablet, a head mounted display, or the like.

FIG. 14B is a schematic view that shows an example of an electronic device using the light emitting apparatus according to the present embodiment. An electronic device 1200 includes a display unit 1201, an operating portion 1202, and a housing 1203. The housing 1203 may contain a circuit, a printed circuit board having the circuit, a battery, and a communication unit. The operating portion 1202 may be a button or may be a touch panel-type response unit. The operating portion may be a biometric authentication unit that identifies a fingerprint to, for example, release a lock. The electronic device including a communication unit may be regarded as a communication device. The electronic device may further have a camera function by including a lens and image pickup elements. An image captured by the camera function is shown on the display unit. The electronic device may be a smartphone, a notebook computer, or the like. The light emitting apparatus according to the present embodiment may be used as the display unit 1201.

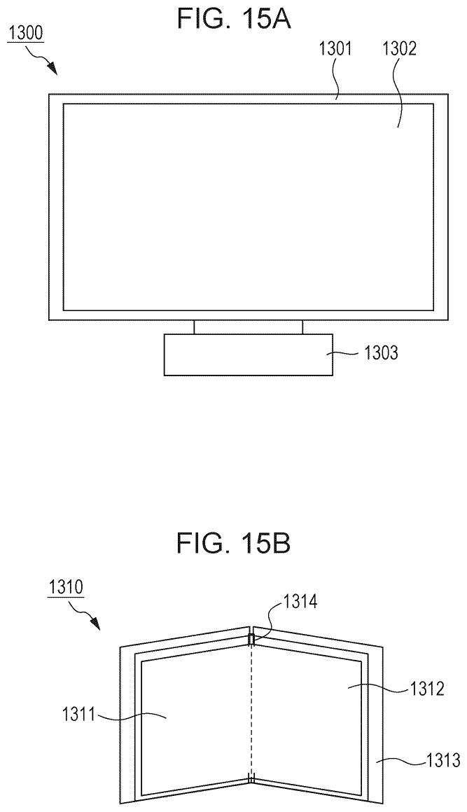

FIGS. 15A and 15B are schematic views that show examples of a display apparatus using the light emitting apparatus according to the present embodiment. FIG. 15A is a display apparatus, such as a television monitor and a PC monitor. The display apparatus 1300 includes a frame 1301 and a display unit 1302. The light emitting apparatus according to the present embodiment may be used as the display unit 1302.

The display apparatus 1300 may include the frame 1301 and a base 1303 that supports the display unit 1302. The base 1303 is not limited to the mode of FIG. 15A. The bottom side of the frame 1301 may serve as a base. The frame 1301 and the display unit 1302 may be curved. The radius of curvature may be greater than or equal to 5000 mm and less than or equal to 6000 mm.

FIG. 15B is a schematic view that shows another example of a display apparatus using the light emitting apparatus according to the present embodiment. A display apparatus 1310 of FIG. 15B is configured to be foldable, and is a so-called foldable display apparatus. The display apparatus 1310 includes a first display unit 1311, a second display unit 1312, a housing 1313, and a folding point 1314. The light emitting apparatus according to the present embodiment may be used as the first display unit 1311 and the second display unit 1312. The first display unit 1311 and the second display unit 1312 may make up a seamless one-sheet display apparatus. The first display unit 1311 and the second display unit 1312 may be separated at the folding point 1314. The first display unit 1311 and the second display unit 1312 may respectively display different images or the first and second display units 1311, 1312 may display one image.

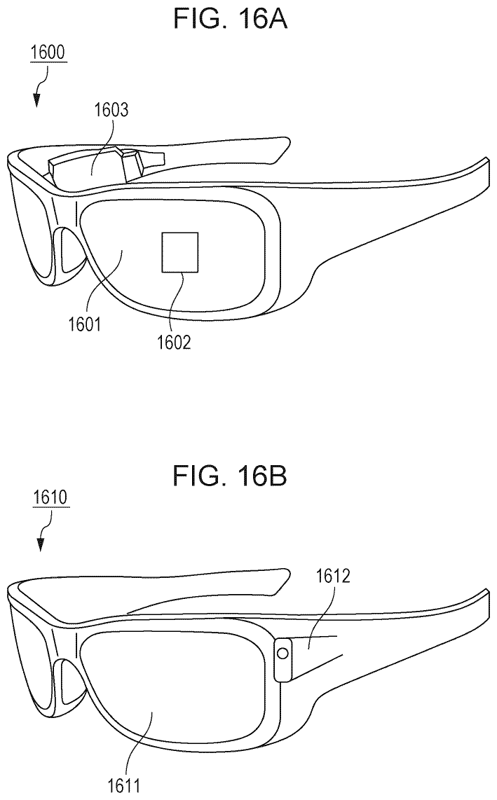

Further application examples of the light emitting apparatus of the present embodiment will be described with reference to FIGS. 16A and 16B. The light emitting apparatus is applicable to a wearable system as a wearable device, such as smartglasses, a head mounted display (HMD), and a smart contact lens. An image capturing and display apparatus used in such application examples includes an image capturing apparatus capable of performing photoelectric conversion of visible light and a display apparatus capable of emitting visible light.

FIG. 16A illustrates glasses 1600 (smartglasses) according to one application example. An image capturing apparatus 1602, such as a CMOS sensor and an SPAD, is provided on the surface side of a lens 1601 of the glasses 1600. In addition, the light emitting apparatus according to the present embodiment is provided on the back surface side of the lens 1601.

The glasses 1600 further include a controller 1603. The controller 1603 functions as a power supply to supply electric power to the image capturing apparatus 1602 and the light emitting apparatus according to any one of the embodiments. The controller 1603 controls the operations of the image capturing apparatus 1602 and the light emitting apparatus. An optical system for condensing light to the image capturing apparatus 1602 is formed in the lens 1601.

FIG. 16B illustrates glasses 1610 (smartglasses) according to one application example. The glasses 1610 include a controller 1612. An image capturing apparatus corresponding to the image capturing apparatus 1602 and a light emitting apparatus (or a display apparatus including the light emitting apparatus) are mounted on the controller 1612. An optical system for projecting light emitted from the light emitting apparatus in the controller 1612 is formed in a lens 1611, and an image is projected onto the lens 1611. The controller 1612 functions as a power supply to supply electric power to the image capturing apparatus and the light emitting apparatus and also controls the operations of the image capturing apparatus and the light emitting apparatus. The controller 1612 may include a line-of-sight detection unit that detects the line of sight of a wearer. Infrared light may be used to detect the line of sight. An infrared emitting unit emits infrared light to the eye of a user gazing at a display image. Infrared light emitted and reflected from the eye is detected by an image capturing unit including light receiving elements. Thus, a captured image of the eye is obtained. A reducer that reduces light from the infrared emitting unit to the display unit in a plan view is provided, so a decrease in image quality is reduced.

The line-of-sight of the user toward the display image is detected from the captured image of the eye, obtained through imaging with infrared light. A selected known technique may be applied to line-of-sight detection using a captured image of an eye. In an example, a line-of-sight detection method based on a Purkinje image caused by reflection of irradiation light on a cornea may be used.

More specifically, a line-of-sight detection process based on a pupil-cornea reflection method is performed. A line-of-sight vector indicating the orientation (rotational angle) of the eye is calculated in accordance with the pupil image contained in a captured image of the eye and a Purkinje image by using the pupil-cornea reflection method. Thus, the line of sight of a user is detected.

The light emitting apparatus according to the embodiment of the present disclosure may include an image capturing apparatus having light receiving elements and may control a display image in accordance with information about the line of sight of a user from the image capturing apparatus.

Specifically, the display apparatus including the light emitting apparatus determines a first display region at which the user gazes and a second display region other than the first display region in accordance with the line-of-sight information. A first display region and a second display region may be determined by the controller of the display apparatus or a first display region and a second display region determined by an external controller may be received. In a display region of the display apparatus, a display resolution of the first display region may be controlled so as to be higher than a display resolution of the second display region. In other words, the resolution of the second display region may be made lower than the resolution of the first display region.

A display region includes a first display region and a second display region different from the first display region, and a region having a higher priority is determined in accordance with line-of-sight information from among the first display region and the second display region. A first field of view region and a second field of view region may be determined by the controller of the display apparatus or a first field of view region and a second field of view region determined by an external controller may be received. The resolution of a region having a higher priority may be controlled so as to be higher than the resolution of a region other than the region having a higher priority. In other words, the resolution of a region having a relatively lower priority may be decreased.

AI may be used to determine a first field of view region or a region having a higher priority. AI may be a model configured to estimate an angle of a line of sight and a distance to an object ahead of the line of sight from an image of an eye by using the images of the eye and corresponding directions in which the eye of the image is actually viewing as training data. The light emitting apparatus, the display apparatus, the image capturing apparatus, or an external apparatus may include an AI program. When the external apparatus includes an AI program, estimated results are transmitted to the light emitting apparatus via communication.

When display control is performed in accordance with line-of-sight detection, the display apparatus is suitably applicable to smartglasses further including an image capturing apparatus that captures an outside image. The smartglasses are capable of displaying captured outside information in real time.

According to the embodiment of the present disclosure, it is possible to improve the output, directivity, and extraction efficiency of infrared light that is emitted from an infrared light emitting element without reducing the viewing angle performance of visible light (display light) emitted from a display light emitting element in a light emitting apparatus.

While the present disclosure has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-052335 filed Mar. 27, 2024, which is hereby incorporated by reference herein in its entirety.

What is claimed is:

1. A light emitting apparatus comprising:
a first light emitting element and a second light emitting element disposed on a substrate; and
a first lens and a second lens respectively disposed in correspondence with the first light emitting element and the second light emitting element, wherein
the first light emitting element has a first light emitting layer containing a chemical compound capable of emitting a light having a wavelength in an infrared range, and
the second light emitting element has a second light emitting layer containing a chemical compound capable of emitting a light having a wavelength in a visible light range, and wherein
where an area of a region that light incident through the first lens in a normal direction of the substrate is input to a light emitting region of the first light emitting element or a surrounding part around the light emitting region is denoted by S₁, an area of the light emitting region of the first light emitting element is denoted by S₁′, an area of a region that light incident through the second lens in the normal direction of the substrate is input to a light emitting region of the second light emitting element or a surrounding part around the light emitting region is denoted by S₂, and an area of the light emitting region of the second light emitting element is denoted by S₂′,
a relationship that a ratio S₁/S₁′ of the S₁ to the S₁′ is closer to one than a ratio S₂/S₂′ of the S₂ to the S₂′ is satisfied.

2. The light emitting apparatus according to claim 1, wherein the first light emitting layer and the second light emitting layer each contain an organic compound.

3. The light emitting apparatus according to claim 1, wherein the second light emitting element includes a color filter.

4. The light emitting apparatus according to claim 3, wherein a length of a perpendicular from a middle point of the first lens to a surface of a lower electrode of the first light emitting element is longer than a length of a perpendicular from a middle point of the second lens to a surface of a lower electrode of the second light emitting element.

5. The light emitting apparatus according to claim 3, wherein a height of the first lens is higher than a height of the second lens.

6. The light emitting apparatus according to claim 3, wherein a radius of the first lens is smaller than a radius of the second lens.

7. The light emitting apparatus according to claim 1, wherein
a center of the light emitting region of the first light emitting element is disposed at a position that overlaps a vertex of the first lens in a plan view, and
a center of the light emitting region of the second light emitting element is disposed at a position that does not overlap a vertex of the second lens in a plan view.

8. The light emitting apparatus according to claim 1, further comprising a light receiving unit capable of receiving infrared light.

9. A display apparatus comprising:
the light emitting apparatus according to claim 1; and
a transistor connected to the light emitting apparatus.

10. An image capturing apparatus comprising:
an optical unit having a plurality of lenses;
an image pickup element arranged to receive light having passed through the optical unit; and
a display unit arranged to display an image captured by the image pickup element, wherein
the display unit includes the light emitting apparatus according to claim 1.

11. An electronic device comprising:
a display unit including the light emitting apparatus according to claim 1;
a housing on which the display unit is provided; and
a communication unit provided in the housing.

12. A light emitting apparatus comprising:
a first light emitting element and a second light emitting element disposed on a substrate; and
a first lens and a second lens respectively disposed in correspondence with the first light emitting element and the second light emitting element, wherein
the first light emitting element has a first light emitting layer containing a chemical compound capable of emitting a light having a wavelength in an infrared range, and
the second light emitting element has a second light emitting layer containing a chemical compound capable of emitting a light having a wavelength in a visible light range, and wherein
where an area of a region that light incident through the first lens in a normal direction of the substrate is input to a light emitting region of the first light emitting element or a surrounding part around the light emitting region is denoted by S₁, an area of the light emitting region of the first light emitting element is denoted by S₁′, an area of a region that light incident through the second lens in the normal direction of the substrate is input to a light emitting region of the second light emitting element or a surrounding part around the light emitting region is denoted by S₂, and an area of the light emitting region of the second light emitting element is denoted by S₂′,
the S₁′ and the S₂′ satisfy a relationship that S₁′<S₂′.
